(19) United States
(12) Patent Application Publication
(10) Pub. No.: US 2026/0339671 A1
(43) Pub. Date: Oct. 29, 2026

(54) COMPUTING DEVICE AND COMPUTING METHOD

(71) Applicant: Preferred Networks, Inc., Tokyo (JP)

(72) Inventors: Gentaro WATANABE, Tokyo (JP); Junichiro MAKINO, Tokyo (JP)

(21) Appl. No.: 19/698,055

(22) Filed: Jun. 4, 2026

Related U.S. Application Data
(63) Continuation of application No. PCT/JP2024/042066, filed on Nov. 27, 2024.
(60) Provisional application No. 63/647,709, filed on May 15, 2024.

(51) Int. Cl. G06F 9/38; G06F 17/16; G11C 29/00

(52) U.S. Cl. CPC G06F 9/3887; G06F 17/16; G11C 29/78

(57) ABSTRACT

A computing device includes a plurality of arithmetic units, one or more first memories coupled to the plurality of arithmetic units, and one or more second memories coupled to the plurality of arithmetic units. The one or more second memories and the plurality of arithmetic units are stacked relative to one another, and at least a part of data stored in the one or more second memories is used by one or more of the plurality of arithmetic units without passing through the one or more first memories.

### CROSS-REFERENCE TO RELATED APPLICATIONS

This application is a continuation application of International Application No. PCT/JP2024/042066 filed on Nov. 27, 2024 and designated the United States, which is based upon and claims priority to U.S. Provisional Application No. 63/647,709 filed on May 15, 2024, the entire contents of which are incorporated herein by reference.

### BACKGROUND

### 1. Field of the Invention

The present disclosure relates to computing devices and computing methods.

### 2. Description of the Related Art

The computing device used in an application that performs processing such as deep learning or the like is required to have a high computational performance in order to perform numerous matrix operations, and a need for a memory having a large storage capacity and a large bandwidth is increasing. Normally, an internal memory incorporated in the computing device has a large bandwidth but a small storage capacity, whereas an external memory connected to the computing device has a large storage capacity but a small bandwidth. For this reason, even when a recent computing device is used, there are cases where it is difficult to efficiently execute an application having a relatively large number of memory accesses.

### SUMMARY

One aspect of the present disclosure provides a computing device having a large storage capacity and a large bandwidth.

A computing device according to an embodiment of the present disclosure includes a plurality of arithmetic units; one or more first memories coupled to the plurality of arithmetic units; and one or more second memories coupled to the plurality of arithmetic units, wherein the one or more second memories and the plurality of arithmetic units are stacked relative to one another, and at least a part of data stored in the one or more second memories is used by one or more of the plurality of arithmetic units without passing through the one or more first memories.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is an exploded perspective view illustrating an example of a general configuration of a computing device according to a first embodiment of the present disclosure;

FIG. 2 is an exploded perspective view illustrating another example of the general configuration of the computing device according to the first embodiment of the present disclosure;

FIG. 3 is an exploded perspective view illustrating still another example of the general configuration of the computing device according to the first embodiment of the present disclosure;

FIG. 4 is a diagram illustrating variations of a method of bonding a logic die and a memory die;

FIG. 5 is a plan view illustrating an example of a configuration of the logic die in FIG. 1;

FIG. 6 is a block diagram illustrating an example of a system including a computer equipped with a plurality of computing devices, and a host;

FIG. 7 is a diagram illustrating examples of a connection between a processing element and a memory block by a memory interface;

FIG. 8 is a circuit block diagram illustrating an example of a processing element PE illustrated in FIG. 5;

FIG. 9 is a circuit block diagram illustrating another example of the processing element PE illustrated in FIG. 5;

FIG. 10 is a block diagram illustrating an example of a connection between the logic die and the memory die in FIG. 1;

FIG. 11 is a diagram illustrating an example of a logical configuration of each memory of the computing device and a connection relationship of each memory;

FIG. 12 is a diagram illustrating an example of the arrangement of memories of the computing device;

FIG. 13 is a diagram illustrating another example of the logical configuration of each memory of the computing device and the connection relationship of each memory;

FIG. 14 is a diagram illustrating an example of a logical configuration of a computing device with hierarchical caches, and a main storage device;

FIG. 15 is a diagram illustrating an example of a physical configuration of the computing device and the main storage device illustrated in FIG. 14;

FIG. 16 is a diagram illustrating an example of redundantly placing matrix arithmetic blocks in the logic die of the computing device;

FIG. 17 is a diagram illustrating an example of redundantly placing memory blocks in the memory die of the computing device;

FIG. 18 is a diagram illustrating an example of redundantly placing the matrix arithmetic blocks and the memory blocks in the computing device;

FIG. 19 is a block diagram illustrating an example of a machine learning model according to a second embodiment of the present disclosure;

FIG. 20 is a flow chart illustrating an example of an inference process of the machine learning model illustrated in FIG. 19; and

FIG. 21 is a block diagram illustrating an example of a hardware configuration of a computer equipped with the computing device described above.

### DETAILED DESCRIPTION

Hereinafter, embodiments of the present disclosure will be described in detail with reference to the accompanying drawings. Although not particularly limited, a computing device may function as an accelerator that performs convolution operations or the like in training or inference of a deep neural network, a large language model (LLM), or the like. In this case, the computing device may also be connected to a central processing unit (CPU) or a graphics processing unit (GPU) and function as a computer that performs scientific and technical computing. In the present specification and claims, the terms “first”, “second”, and the like are used merely as a method for distinguishing between two or more elements, and are not necessarily intended to impose a technical meaning, such as a temporal aspect, a spatial aspect, an order, a quantity, and the like on the elements. Thus, a reference to first and second elements, for example, does not necessarily mean that only two elements may be employed there nor that the first element must precede the second element, and it does not necessarily mean that the first element must be present in order for the second element to be present.

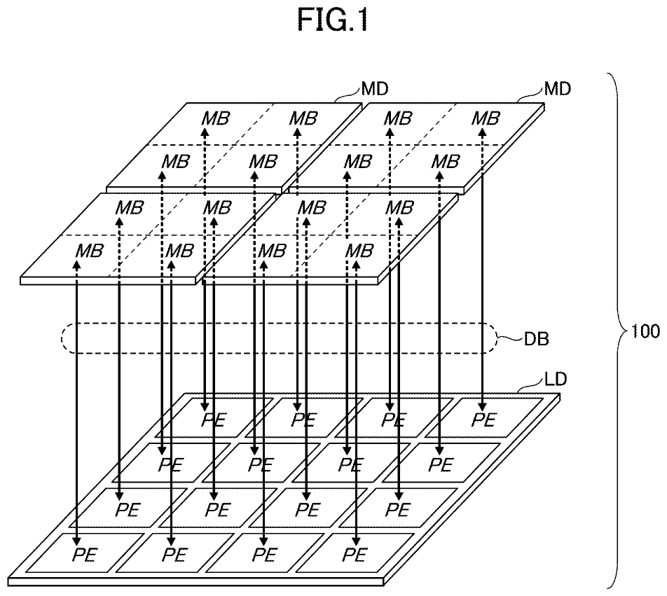

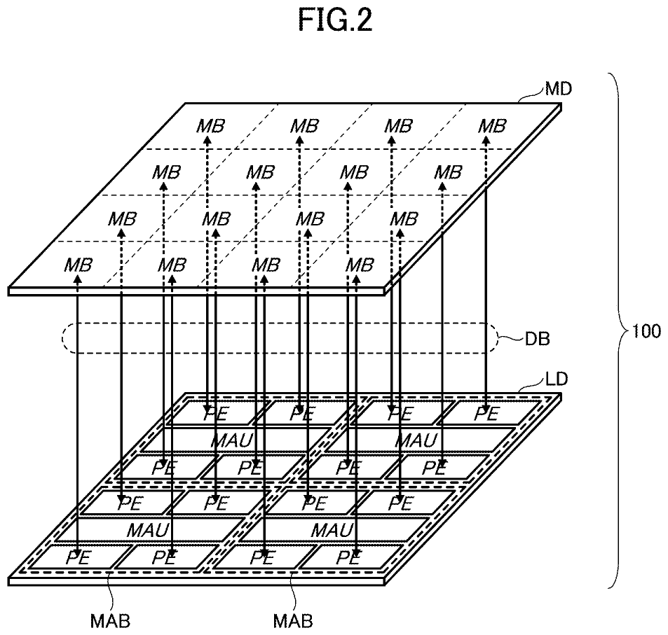

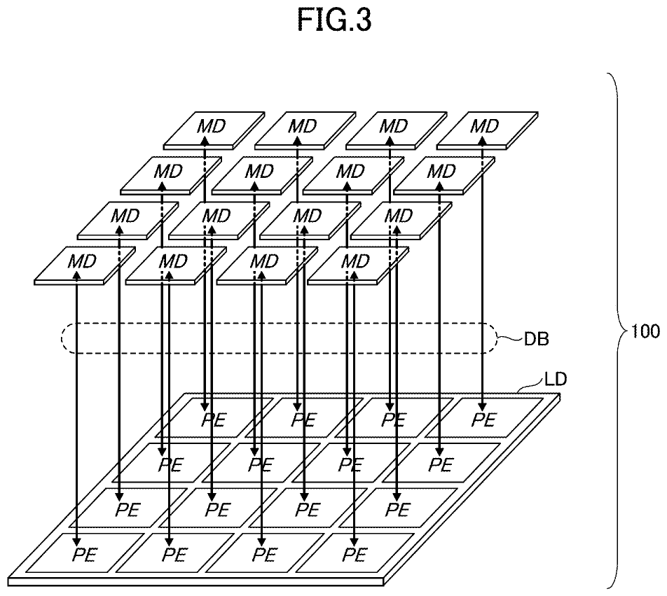

FIG. 1, FIG. 2, and FIG. 3 are exploded perspective views illustrating a general configuration of a computing device according to a first embodiment of the present disclosure. A computing device 100 illustrated in FIG. 1 through FIG. 3 may include a logic die LD and a memory die MD that are three-dimensionally integrated. The logic die LD is an example of a first die, and the memory die MD is an example of a second die.

The logic die LD may include a plurality of processing elements PE that can operate in parallel. The processing element PE is an example of an arithmetic unit. The logic die LD may be connected to one or more memory dies MD. As illustrated in FIG. 1 through FIG. 3, the logic die LD and the memory die MD may be stacked and connected relative to each other via a data bus DB. A control signal line (not illustrated) used for reading and writing data may be connected between the logic die LD and the memory die MD. Further, “stacked”, as in “dies are stacked”, includes being disposed in an upward direction, in a downward direction, or in both the upward and downward directions. Accordingly, memory blocks MB included in the memory die MD, for example, may be disposed in the upward direction, in the downward direction, or in the upward and downward directions of matrix arithmetic blocks MAB and the processing elements PE included in the logic die LD. In addition, an element other than the die may be inserted between the plurality of dies to be stacked relative to one another as long as a broadband data transfer can be maintained.

When the logic die LD and the memory die MD are stacked relative to each other, a distance between the dies LD and MD can be set to be less than or equal to a thickness of the die. For this reason, compared to a case where the logic die LD and the memory die MD are disposed side by side on the same substrate, for example, a load capacitance of the data bus DB can be significantly reduced, and a propagation delay time of a data signal or the like transmitted to the data bus DB can be significantly shortened. As a result, it is possible to improve a processing performance (or a computational performance) of the computing device 100.

As illustrated in FIG. 1 and FIG. 2, the memory die MD may include a plurality of memory blocks MB, where each memory block MB is disposed to face a processing element PE. Each memory block MB of the plurality of memory blocks MB may be used exclusively by the processing element PE facing the memory block MB. Although FIG. 1 and FIG. 2 illustrate examples in which each memory die MD is connected to a plurality of processing elements PE, the plurality of memory dies MD may be disposed to face the plurality of processing elements PE, respectively, and each memory die MD may be connected to the facing processing element PE in a 1:1 manner as illustrated in FIG. 3. That is, the memory die MD and the processing elements PE may be connected in a 1:m manner, where m is an integer greater than or equal to 1. Each memory block MB of the plurality of memory blocks MB included in one or more memory dies MD may be used as a scratchpad memory of the processing element PE connected thereto.

As illustrated in FIG. 1 and FIG. 2, each memory die MD may include an arbitrary number of memory blocks MB. The number of memory dies MD connected to the logic die LD may be determined according to the number of memory blocks MB included in each memory die MD. As illustrated in FIG. 2, the logic die LD may include one or more matrix arithmetic blocks MAB. Each matrix arithmetic block MAB may include one or more processing elements PE and a matrix arithmetic unit MAU.

For example, the memory die MD may be a dynamic random access memory (DRAM), a static random access memory (SRAM), a magnetoresistive random access memory (MRAM), a phase-change RAM (PRAM), a flash memory, or the like. The memory die MD may include one or more DRAMs, one or more MRAMs, one or more PRAMs, one or more flash memories, or the like.

By three-dimensionally integrating the logic die LD and the memory dies MD, the lengths of the data bus DB and the control signal line can be set to be less than or equal to the thickness of the die. Consequently, it is possible to minimize an interconnect capacitance and an interconnect delay, and to suppress an increase in the charge and discharge currents of the data bus DB and the control signal line.

The memory block MB and the memory die MD may be used as a work memory of the processing element PE. By using the work memory provided outside the logic die LD, a storage capacity of the work memory can be significantly increased compared to the case where only the work memory inside the logic die LD is used. Accordingly, the computing device 100 having a large capacity and a large bandwidth can be realized, and a memory-intensive application with a high memory access frequency can be executed efficiently. As a result, the computing device 100 can perform training, inference, scientific and technical computing, or the like of a deep neural network that requires a large amount of data processing at a high speed and with a low power.

FIG. 1 through FIG. 3 illustrate examples in which the arithmetic unit, such as the processing element PE, the matrix arithmetic unit MAU, the matrix arithmetic block MAB, or the like, and the memory block MB are formed on different dies. However, various arithmetic units and the memory block MB may be formed in different layers of one die, and the layer of the arithmetic unit and the layer of the memory block MB may be connected to each other through a via, such as a through silicon via (TSV) or the like.

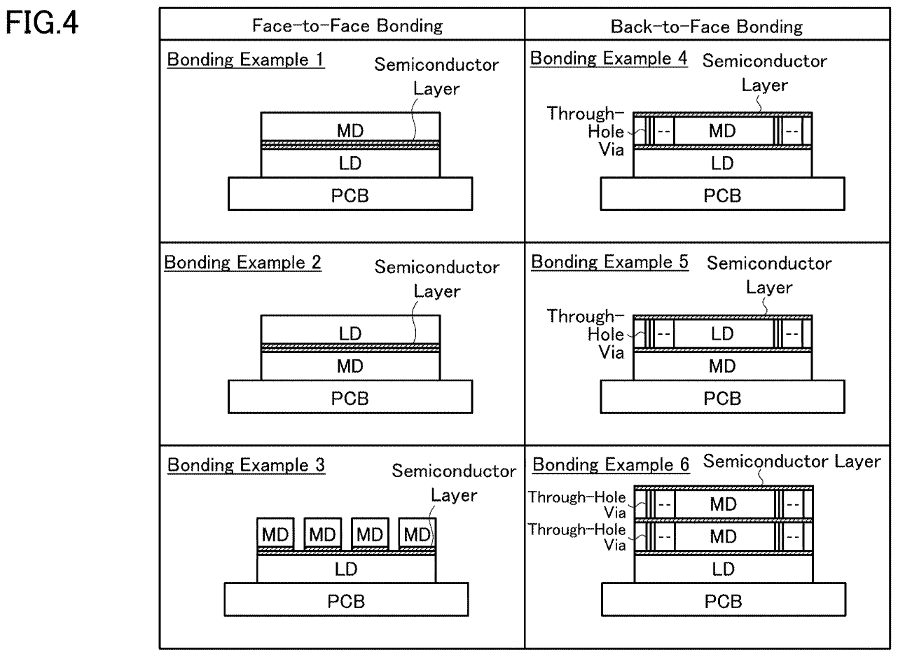

FIG. 4 is a diagram illustrating variations of a method of bonding the logic die LD and the memory die MD. The logic die LD and the memory die MD may be connected to each other by face-to-face bonding or back-to-face bonding. In the face-to-face bonding, the logic die LD and the memory die MD may be connected to each other by causing semiconductor layers in which elements such as transistors and interconnects are formed on a Si substrate or the like to face each other. In the back-to-face bonding, the logic die LD and the memory die MD may be connected to each other with the semiconductor layers located on a side opposite to a printed circuit board (or a substrate). The computing device 100 may be in a form of a package including the printed circuit board, the logic die LD, and the memory die MD.

Bonding examples 1 through 3 illustrate the face-to-face bonding, and bonding examples 4 through 6 illustrate the back-to-face bonding. A stacked structure (the stacking order, the number of stacks, and the like) of the logic die LD and the memory die MD and a stacked structure (the stacking order, the number of stacks, and the like) of the processing element PE included in the logic die LD and the memory block MB included in the memory die MD are not limited to those of the bonding examples 1 through 6. As illustrated in FIG. 2, the memory die MD may include a plurality of memory blocks MB, and the logic die LD may include a plurality of matrix arithmetic blocks MAB, where each matrix arithmetic block MAB includes a plurality of processing elements PE.

As illustrated in the bonding example 1, the logic die LD and the memory die MD may be disposed on the printed circuit board in this order and may be connected in a face-to-face manner. As illustrated in the bonding example 2, the memory die MD and the logic die LD may be disposed on the printed circuit board in this order and may be connected in the face-to-face manner. As illustrated in the bonding example 3, a plurality of memory dies MD may be disposed on the logic die LD, and the logic die LD and each memory die MD of the plurality of memory dies MD may be connected in the face-to-face manner.

In the face-to-face bonding, the logic die LD and the memory die MD may be connected to each other by hybrid bonding or may be connected to each other by microbumps. The data bus DB illustrated in FIG. 1 and FIG. 2 may correspond to the hybrid bonding or the micro-bumps.

As illustrated in the bonding example 4, the logic die LD and the memory die MD may be disposed in this order on the printed circuit board with the semiconductor layers facing the side opposite to the printed circuit board, and may be connected in a back-to-face manner. In this case, the semiconductor layer of the memory die MD may be connected to the semiconductor layer of the logic die LD through a through-via provided in the memory die MD.

As illustrated in the fifth bonding example, the memory die MD and the logic die LD may be disposed in this order on the printed circuit board with the semiconductor layers facing the side opposite to the printed circuit board, and may be connected in the back-to-face manner. In this case, the semiconductor layer of the logic die LD may be connected to the semiconductor layer of the memory die MD through a through-via, such as a TSV or the like provided in the logic die LD. The data bus DB illustrated in FIG. 1 and FIG. 2 may correspond to the through-via.

As illustrated in the sixth bonding example, a plurality of memory dies MD may be stacked on the logic die LD. In this case, the stacked memory dies MD may be connected to each other by a through-via. Three or more memory dies MD may be stacked on the logic die LD.

The logic die LD and the memory die MD may be connected to each other via a wiring board, such as a silicon interposer or the like. By sandwiching the silicon interposer between the logic die LD and the memory die MD, for example, a data terminal of the logic die LD and a data terminal of the memory die MD can be easily aligned. In addition, a plurality of logic dies LD and a plurality of memory dies MD may be stacked and connected to one another.

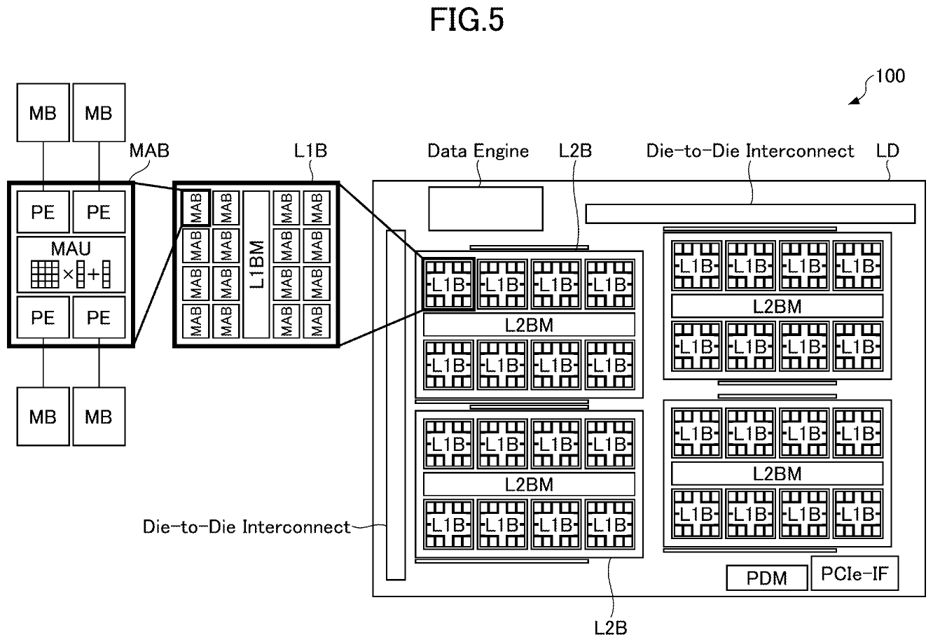

FIG. 5 is a plan view illustrating an example of a configuration of the logic die LD in FIG. 1. The logic die LD may include a plurality of blocks L2B, a data engine, die-to-die interconnect, a peripheral component interconnect express interface (PCIe-IF), and a memory PDM.

Each block L2B may have a plurality of blocks L1B and a memory L2BM. Each block L1B may include a plurality of matrix arithmetic blocks MAB and a memory L1BM. As illustrated in FIG. 2, each matrix arithmetic block MAB may include a plurality of processing elements PE and a matrix arithmetic unit MAU. A storage capacity of the memory L2BM may be larger than a storage capacity of the memory L1BM, and a storage capacity of the memory block MB may be larger than the storage capacity of the memory L1BM.

The plurality of processing elements PE may be connected to the plurality of memory blocks MB, respectively, and at least a portion of data stored in the memory blocks MB may be used in the matrix arithmetic unit MAU without passing this portion of the data through the memory L1BM. The matrix arithmetic unit MAU may be configured by a systolic array.

As illustrated in FIG. 5, the logic die LD may include blocks L1B and L2B that include a predetermined number of hierarchical matrix arithmetic blocks MAB, and the memories L1BM and L2BM may have hierarchical structures. The matrix arithmetic block MAB is an example of a first hierarchical block, the block L1B is an example of a second hierarchical block, and the block L2B is an example of a third hierarchical block. The memory L1BM is an example of a first memory, the memory block MB is an example of a second memory, and the memory L2BM is an example of a third memory. The memory PDM is an example of a fourth memory. All of the matrix arithmetic blocks MAB installed on the logic die LD may operate according to the same instruction.

The logic die LD may include four blocks L2B, and each block L2B may include eight blocks L1B and one memory L2BM. Each block L1B may include 16 matrix arithmetic blocks MAB and one memory L1BM, and each matrix arithmetic block MAB may include four processing elements PE and one matrix arithmetic unit MAU. The matrix arithmetic block MAB may have a configuration not including the matrix arithmetic unit MAU.

The number of elements included in the logic die LD may not be limited to that in FIG. 5. For example, the logic die LD may have two blocks L2B, and each block L2B may have four blocks L1B and one memory L2BM. Each block L1B may include 16 matrix arithmetic blocks MAB and one memory L1BM, and each matrix arithmetic block MAB may include 8 processing elements PE and one matrix arithmetic unit MAU.

In the logic die LD, a large number of matrix arithmetic units MAU are disposed in a distributed manner, but by connecting the memory block MB having a large capacity and a large bandwidth to each processing element PE, data can be supplied to each matrix arithmetic unit MAU of the plurality of matrix arithmetic units MAU disposed in a distributed manner without stalling the computation. That is, it is possible to suppress the occurrence of a time period during which the matrix arithmetic unit MAU cannot perform the computation due to an insufficient memory bandwidth, which in turn would deteriorate a computational speed. One or both of the matrix arithmetic unit MAU and the processing element PE are examples of an arithmetic unit. The arithmetic unit may be any one of an arithmetic circuit, a processing circuit, and processing circuitry.

The number of blocks L2B installed on the logic die LD, the number of blocks L1B installed on each block L2B, the number of matrix arithmetic blocks MAB installed on each block L1B, and the number of processing elements PE installed on each matrix arithmetic block MAB are preferably 2ⁿ, where n is an integer greater than or equal to 1.

The data engine may control transfer of the data stored in the memory PDM to the memory L2BM or the memory L1B from the outside of the logic die LD, and may control transfer of the data among the memory L2BM, the memory L1B, and the matrix arithmetic block MAB.

The die-to-die interconnect may be used to connect the computing device 100 to another computing device 100. The PCIe-IF may transmit and receive data, instructions, and the like to and from a host or a device connected externally to the computing device 100. The memory PDM may function as a buffer memory that holds the data and the like transmitted and received via the PCIe-IF. For example, the PCIe-IF may be configured by a field programmable gate array (FPGA).

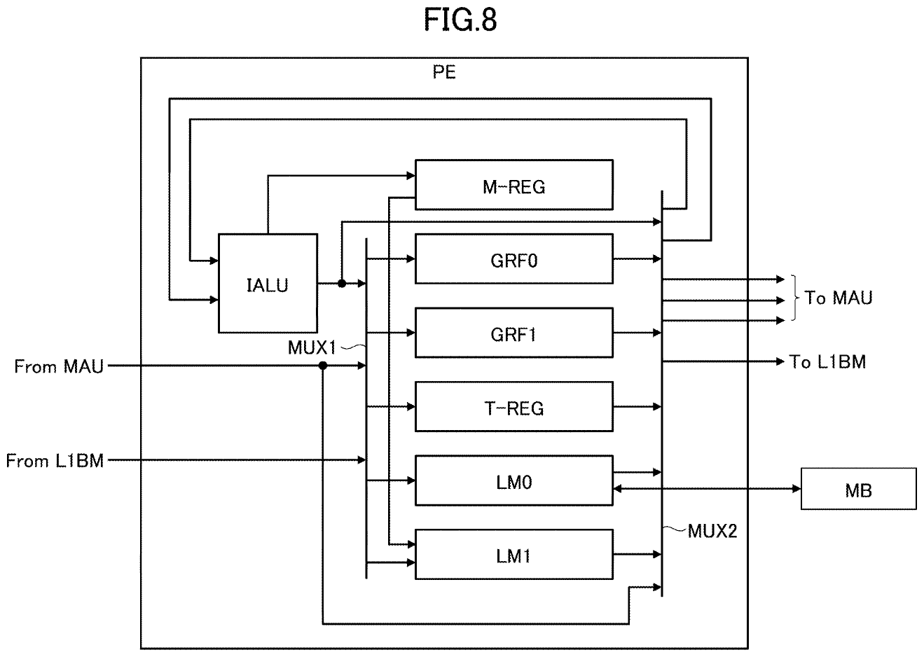

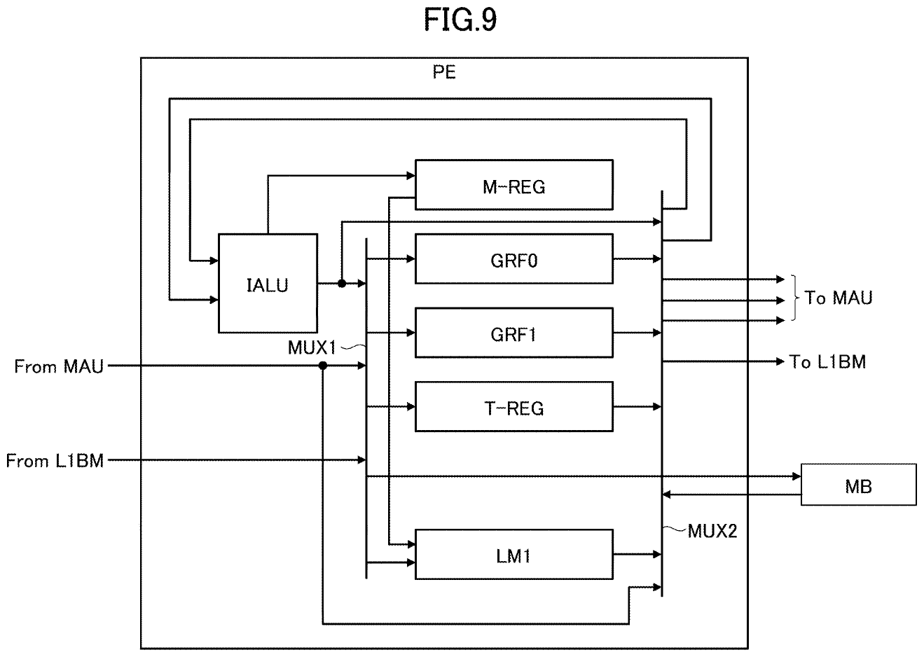

Each processing element PE may be connected to the memory block MB of the memory die MD as illustrated in FIG. 1 and FIG. 2. Each processing element PE may not directly access the memory blocks MB other than the memory block MB directly connected thereto, and a program may be devised so as to operate without using computation results of other processing elements PE. Examples of the processing element PE are illustrated in FIG. 8 and FIG. 9. For example, the matrix arithmetic unit MAU may execute a single instruction multiple data (SIMD) instruction. The computing device 100 may have a SIMD architecture in which all of the matrix arithmetic blocks MAB included in the computing device 100 are operated by a single instruction.

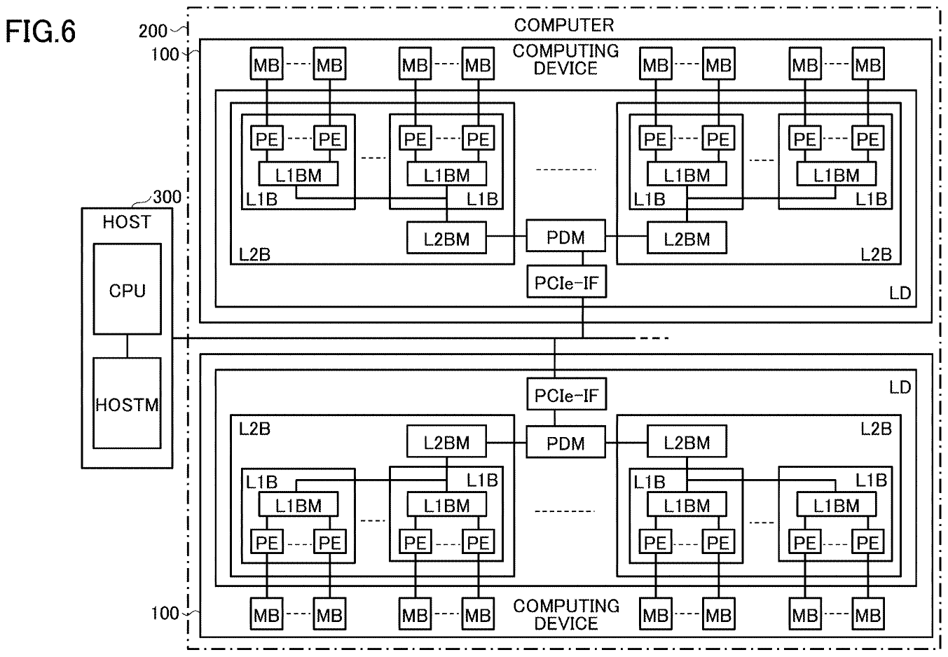

FIG. 6 is a block diagram illustrating an example of a system including a computer 200 equipped with a plurality of computing devices 100, and a host 300. The computer 200 illustrated in FIG. 6 includes the plurality of computing devices 100 connected to one another. For example, the computer 200 may have a form of an electronic circuit board installed with the plurality of computing devices 100. In FIG. 6, the computer 200 includes two computing devices 100, but the number of computing devices 100 may be one or three or more. For example, the computer 200 may perform inference, such as a large language model (LLM) or the like. The host 300 may include a CPU and a host memory HOSTM.

Each computing device 100 may be connected to the host 300 via the PCIe-IF and receive information, such as data, instructions, and the like transferred from the host memory HOSTM by a control program executed by the CPU of the host 300. Transfer of the information between the host memory HOSTM and the computing device 100 may be performed by direct memory access (DMA).

Each computing device 100 may perform the computation in the matrix arithmetic block MAB in FIG. 5, based on a computation instruction received from the host 300, or may perform a data transfer process based on a data transfer instruction received from the host 300. For example, the computation to be performed and the matrix arithmetic block MAB that is to perform the computation may be instructed from the host 300 to each computing device 100 by software.

The data transfer with respect to the memory PDM, the memory L2BM, the memory L1BM, or the memory die MD may be performed by executing the data transfer instruction. Further, after the data to be subjected to the computation is transferred to the memory die MD, each computing device 100 may perform the computation using the processing element PE or the matrix arithmetic unit MAU, based on the computation instruction received from the host 300.

For example, a program including various instruction codes transferred from the host 300 to the computing device 100 may be generated by a compiler device (not illustrated) or may be stored in the host memory HOSTM. In FIG. 6, lines connecting the elements of the computing device 100 indicate data transfer paths (or data transfer lines), and the computation instruction and various control information may be transferred through paths (not illustrated) different from the data transfer paths.

In FIG. 6, each processing element PE is connected to the memory block MB as illustrated in FIG. 1 and FIG. 2, but a plurality of processing elements PE may be connected to one memory block MB, or each processing element PE may be connected to a plurality of memory blocks MB.

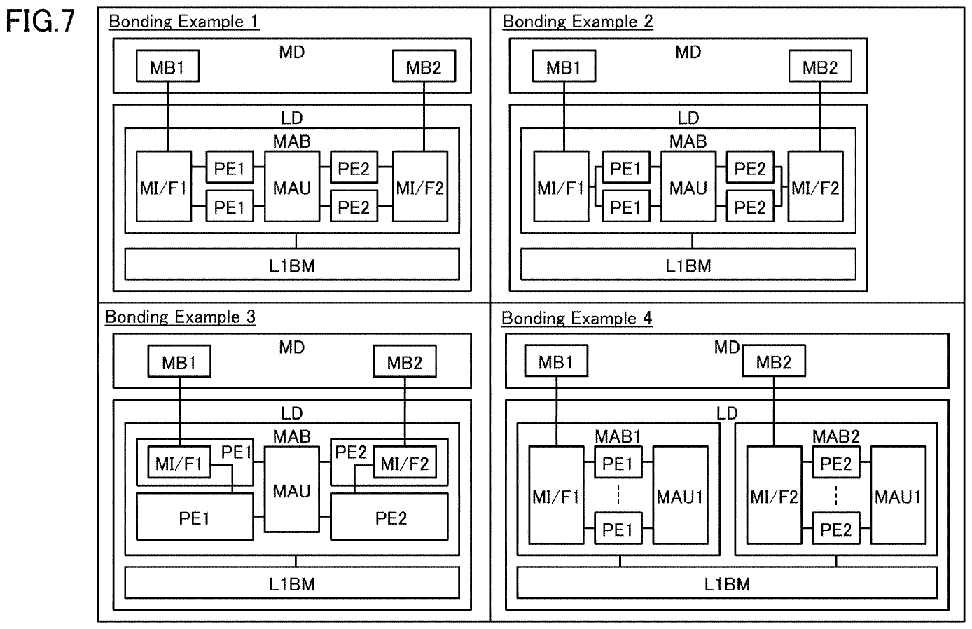

FIG. 7 is a diagram illustrating examples of a connection between the processing element PE and the memory block MB by a memory interface MI/F. In the bonding example 1, two processing elements PE1 of the matrix arithmetic block MAB may be connected to a memory block MB1 via a memory interface MI/F1, and two processing elements PE2 of the matrix arithmetic block MAB may be connected to a memory block MB2 via a memory interface MI/F2. That is, the memory interface MI/F1 may connect at least one processing element PE1 to one or more memory blocks MB1, and the memory interface MI/F2 may connect at least one processing element PE2 to one or more memory blocks MB2. In addition, the memory interface MI/F1 may connect at least one processing element PE1 to a predetermined memory block MB1 of the one or more memory blocks MB1, and the memory interface MI/F2 may connect at least one processing element PE2 to a predetermined memory block MB2 of the one or more memory blocks MB2. The memory interface MI/F1 is an example of a first memory interface, and the processing element PE1 connected to the memory interface MI/F1 is an example of a first arithmetic unit. The memory interface MI/F2 is an example of a second memory interface, and the processing element PE2 connected to the memory interface MI/F2 is an example of a second arithmetic unit.

Moreover, two processing elements PE1 may be independently connected to the memory interface MI/F1, or two processing elements PE2 may be independently connected to the memory interface MI/F2. In this case, the memory interface MI/F1 or MI/F2 has an arbitration circuit that arbitrates memory access instructions from the two processing elements PE1 or PE2.

In the bonding example 2, two processing elements PE1 may be connected in common to the memory interface MI/F1, or two processing elements PE2 may be connected in common to the memory interface MI/F 2. In the bonding example 1 or the bonding example 2, the number of processing elements PE1 or PE2 connected to the memory interface MI/F1 or MI/F2 may be three or more.

In the bonding example 3, one processing element PE1 of the two processing elements PE1 may have the memory interface MI/F1, and one processing element PE2 of the two processing elements PE2 may have the memory interface MI/F2. In this case, the other processing element PE1 of the two processing elements PE1 may be connected to the memory interface MI/F1 of the one processing element PE1, and may be connected to the memory block MB1 via the memory interface MI/F1. Similarly, the other processing element PE2 of the two processing elements PE2 may be connected to the memory interface MI/F2 of the one processing element PE2, and may be connected to the memory block MB2 via the memory interface MI/F2.

In the bonding example 3, the matrix arithmetic block MAB may include three or more processing elements PE1 and three or more processing elements PE2. In this case, one processing element PE1 of the three or more processing elements PE1 may have the memory interface MI/F1, or one processing element PE2 of the three or more processing elements PE2 may have the memory interface MI/F2. Three or more memory blocks MB may be connected to one matrix arithmetic block MAB.

In the bonding example 4, the memory interface MI/F 1 or MI/F 2 may be provided for each of the matrix arithmetic blocks MAB1 and MAB2. In this case, a plurality of processing elements PE1 (for example, four processing elements PE1) of the matrix arithmetic block MAB1 may be connected to the memory block MB1 via the memory interface MI/F1, and a plurality of processing elements PE2 (for example, four processing elements PE2) of the matrix arithmetic block MAB2 may be connected to the memory block MB2 via the memory interface MI/F2. One memory block MB may be connected to a plurality of matrix arithmetic blocks MAB.

As illustrated in the bonding examples of FIG. 7, the memory interfaces MI/F1 and MI/F2 may be used exclusively for access to the memory blocks MB1 and MB2 provided in the memory die MD, respectively. The memory interfaces MI/F1 and MI/F2 are not used for the access to the memory L1BM and the memory L2BM (not illustrated).

Further, although FIG. 7 illustrates examples in which one memory interface MI/F1 or MI/F2 is provided in correspondence with a plurality of processing elements PE1 or a plurality of processing elements PE2, a memory interface MI/F may be provided for each processing element PE. In this case, the memory interface MI/F may be incorporated, integrated, or embedded in each processing element PE.

FIG. 8 is a circuit block diagram illustrating an example of the processing element PE illustrated in FIG. 5. The processing element PE includes an integer arithmetic logic unit IALU, registers M-REG, GRF0, GRF1, and T-REG, local memories LM0 and LM1, and multiplexers MUX1 and MUX2. For example, the local memories LM0 and LM1 may be configured by SRAMs. The local memories LM0 and LM1 are examples of a fifth memory.

The register M-REG may mask at least a part of computation result data of the integer arithmetic logic unit IALU, and may prevent the computation result data from being written to the local memory LM1. The registers GRF0 and GRF1 may be general purpose registers that hold data used for the computation or the computation result data. In addition, the registers GRF0 and GRF1 may be two-port registers capable of writing data and reading data in parallel. The register T-REG may be used to temporarily hold data.

The local memory LM0 may be a buffer memory that holds data read from and data written to the memory block MB. In this case, the local memory LM0 may be connected to a corresponding memory block MB via the memory interface MI/F1 or MI/F2 illustrated in FIG. 7. Because the memory block MB is connected only to the local memory LM0 and is not connected to the multiplexers MUX1 and MUX2, the data input to and the data output from the memory block MB is transferred only through the local memory LM0.

For example, a storage capacity of the local memory LM0 may be 16 Mbytes, and the local memory LM0 may read data from or write data to the memory block MB at 8 bytes/cycle. A data input/output port of the memory block MB may be 8 bytes. The local memory LM0 may hold data that is not read from or written to the memory block MB.

For example, the local memory LM1 may hold data used by the integer arithmetic logic unit IALU, and may hold the computation result data of the integer arithmetic logic unit IALU. For example, a storage capacity of the local memory LM1 may be 16 kbytes, and the reading of data from or the writing of data to the local memory LM1 may be performed at 8 bytes/cycle. The local memories LM0 and LM1 may be single-port memories that can perform the reading or writing of data, or may be dual-port memories that can perform reading and writing of data at the same time or substantially at the same time.

The multiplexer MUX1 may transfer any of computation result data of the integer arithmetic logic unit IALU, computation result data of the matrix arithmetic unit MAU, or data from the memory L1BM to any of the register GRF0, the register GRF1, the register T-REG, the local memory LM0 or the local memory LM1 according to an instruction. The multiplexer MUX2 may transfer any of the computation result data of the integer arithmetic logic unit IALU, the data from the register GRF0, the register GRF1, the register T-REG, the local memory LM0, the local memory LM1, or the matrix arithmetic unit MAU to any of the integer arithmetic logic unit IALU, the matrix arithmetic unit MAU, or the memory L1BM according to an instruction.

The processing element PE may supply data read from the memory block MB via the local memory LM0 to the integer arithmetic logic unit IALU or the matrix arithmetic unit MAU to cause the integer arithmetic logic unit IALU or the matrix arithmetic unit MAU to perform a computation. The processing element PE may write back computation result data output from the integer arithmetic logic unit IALU or the matrix arithmetic unit MAU to the memory block MB via the local memory LM0. A basic operation of the logic die LD includes the computation of the integer arithmetic logic unit IALU or the matrix arithmetic unit MAU performed on the data read from the memory block MB and the write back of the computation result data to the memory block MB.

FIG. 9 is a circuit block diagram illustrating another example of the processing element PE illustrated in FIG. 5. The processing element PE illustrated in FIG. 9 may not include the local memory LM0, and one of the outputs of the multiplexer MUX1 and one of the inputs of the multiplexer MUX2 may be connected to the memory block MB via the memory interface MI/F (not illustrated).

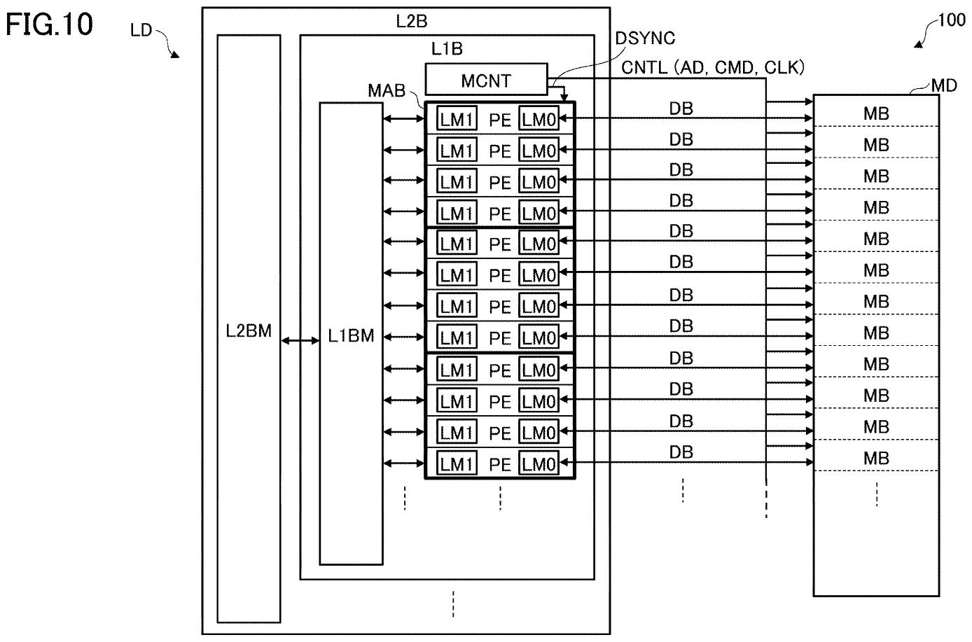

FIG. 10 is a block diagram illustrating an example of a connection between the logic die LD and the memory die MD in FIG. 1. The block L1B may include a memory controller MCNT that generates a control signal CNTL for controlling reading data from and writing data to the memory block MB, in addition to the plurality of matrix arithmetic blocks MAB and the memory L1BM illustrated in FIG. 2. The memory controller MCNT may include some of the functions of the memory interfaces MI/F1 and MI/F2 illustrated in FIG. 7. For example, the control signal CNTL may include an address signal AD, a command signal CMD for instructing a read access request or a write access request, a clock signal CLK, and the like.

The memory controller MCNT may output a data synchronization signal DSYNC to each local memory LM0 in the block L1B. The memory controller MCNT may output a data synchronization signal DSYNC indicating a timing to write data, that is read from the memory block MB onto the data bus DB in response to the control signal CNTL, to the local memory LM0 during a read access to the memory block MB. The memory controller MCNT may output a data synchronization signal DSYNC indicating a timing to output data to be written to the memory block MB, from the local memory LM0 to the data bus DB in response to the control signal CNTL during a write access to the memory block MB.

For example, the memory controller MCNT may generate the control signal CNTL and the data synchronization signal DSYNC that are common to all of the local memories LM0 installed in the block L1B. In this case, all of the memory blocks MB connected to the block L1B operate in synchronization with one another. Alternatively, the memory controller MCNT may generate the control signal CNTL and the data synchronization signal DSYNC that are common to each predetermined number of local memories LM0 installed in the block L1B.

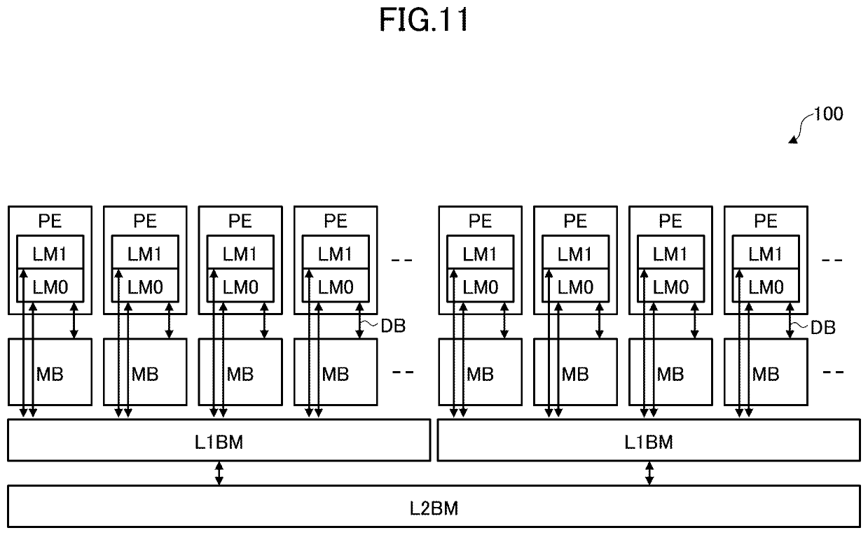

FIG. 11 is a diagram illustrating an example of a logical configuration of each memory of the memories L2BM, L1BM, LM0, and LM1 of the computing device 100 and a connection relationship of each memory. The local memories LM0 and LM1 may be connected to the corresponding memory L1BM. The memory L1BM may be connected to the corresponding memory L2BM. The memory L1BM and the memory L2BM may not be directly connected to the memory blocks MB, and may be utilized for data transfer between the processing elements PE or for data transfer to and from the outside of the logic die LD. Alternatively, the memory L1BM and the memory L2BM may be directly connected to the memory blocks MB or external memories different from the memory blocks MB, and may be utilized for data transfer. Further, the processing element PE may have a configuration not including the local memory LM1.

Each memory block MB is disposed near the corresponding processing element PE so as to face the corresponding processing element PE, and may be connected to the corresponding local memory LM0 by hybrid-bonding terminals of the logic die LD and the memory die MD, for example. This makes it possible to reduce a data movement distance when reading data from or writing data to the memory block MB, and to suppress an increase in both interconnect length and power consumption even in a case where the bandwidth of the memory block MB increases.

The processing elements PE connected to the memory blocks MB in a 1:1 manner are preferably connected to the memory blocks MB located immediately above or immediately below the processing elements PE in order to reduce the interconnect length. However, each processing element PE may be disposed at a position deviated from the position directly above or directly below the corresponding memory block MB as long as the processing element PE is disposed closer to the corresponding memory block MB than to an adjacent processing element PE in the plan view. In other words, each processing element PE need only be connected to the closest memory block MB in the plan view. As a result, it is possible to suppress deterioration of the bandwidth of the memory block MB.

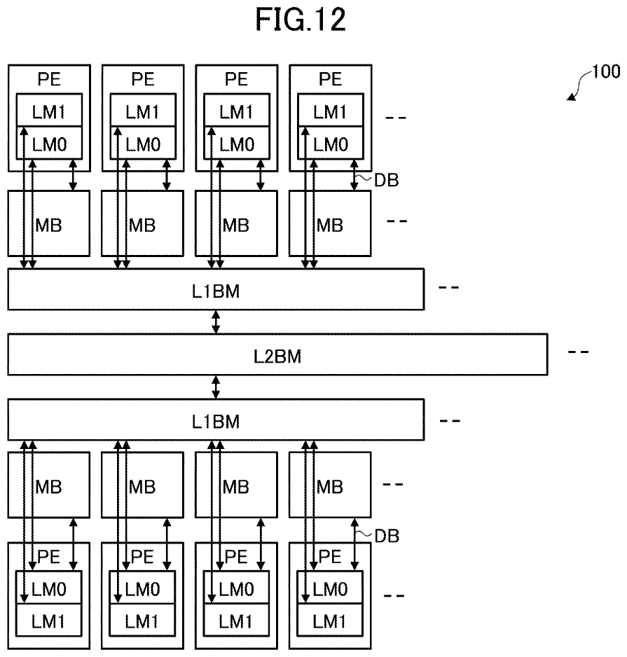

FIG. 12 is a diagram illustrating an example of arrangement of the memories L2BM, L1BM, LM0, and LM1 of the computing device 100. As illustrated in FIG. 1 and FIG. 2, because the memory die MD including the memory blocks MB is disposed above or below the logic die LD, the connection between the memory block MB and the local memory LM0 can be distributed within the chip without becoming concentrated at portions of the memory die MD and the logic die LD. As a result, the memory die MD and the logic die LD can be connected to each other using a very large number of data buses DB.

For example, the memory die MD and the logic die LD may be connected to each other so that data can be read or written at 8 bytes/cycle for each processing element PE. Accordingly, compared to a case where the local memory LM0 having a small memory capacity is used to hold intermediate data of the computation, for example, a memory block MB having a large memory capacity can be used without deteriorating the bandwidth.

The memory block MB is not limited to being connected to each processing element PE, and may be connected to each matrix arithmetic block MAB (every four processing elements PE). In addition, the memory block MB may be connected to every two or more matrix arithmetic blocks MAB. As illustrated in FIG. 7, two memory blocks MB1 and MB2 may be connected to one matrix arithmetic block MAB, and each of the memory blocks MB1 and MB2 may be shared by two processing elements PE1 or two processing elements PE2. Further, the memory block MB may be connected to every four matrix arithmetic blocks MAB (every 16 processing elements PE). The number of processing elements PE connected to each memory block MB may be determined by taking into consideration constraints, such as interface specifications of the memory block MB or the like.

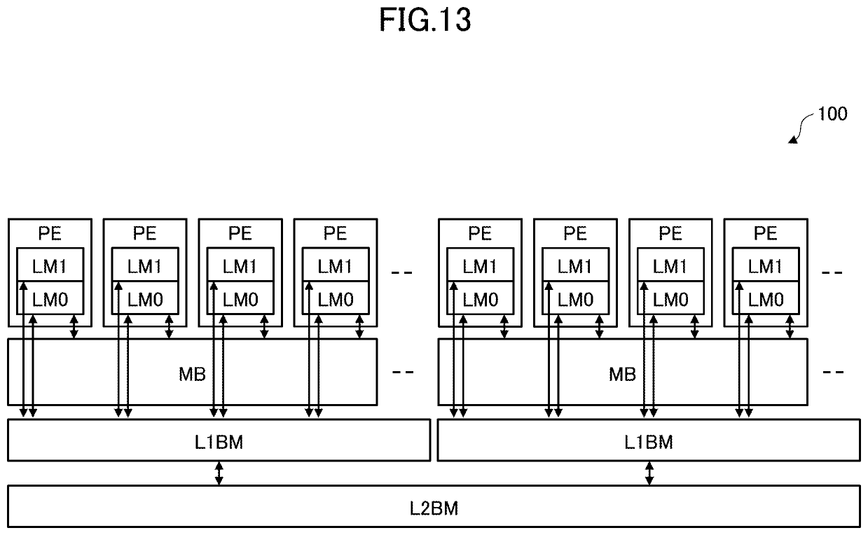

FIG. 13 is a diagram illustrating another example of the logical configuration of each memory of the memories L2BM, L1BM, LM0, and LM1 of the computing device 100 and the connection relationship of each memory. The memory block MB may be connected to every four processing elements PE. The configuration illustrated in FIG. 13 is the same as that illustrated in FIG. 11 except for the different number of processing elements PE connected to the memory block MB.

When four processing elements PE are allocated to one memory block MB, the bandwidth of the port of the memory block MB may be set to four times the bandwidth of the port of the memory block MB in FIG. 11. This makes it possible to equalize the bandwidth per processing element PE to that in FIG. 11.

In FIG. 13, a constraint occurs in which the four processing elements PE access different portions of the data held in a storage area of the same address of one memory block MB. If each processing element PE reads or writes 16 bytes of data per cycle in the configuration illustrated in FIG. 11, each processing element PE of the four processing elements PE in FIG. 13 may read or write 64 bytes of data per cycle. In this state, each processing element PE may read or write four 16-byte data obtained by dividing (or splitting) 64 bytes of data into four equal parts. The number of processing elements PE allocated to one memory block MB may be other than those illustrated in FIG. 11 and FIG. 13.

In addition, in a case where a plurality of processing elements PE are allocated to one memory block MB, a memory die MD may be disposed in place of each memory block MB. Moreover, the memory die MD may be disposed in place of each memory block MB illustrated in FIG. 5.

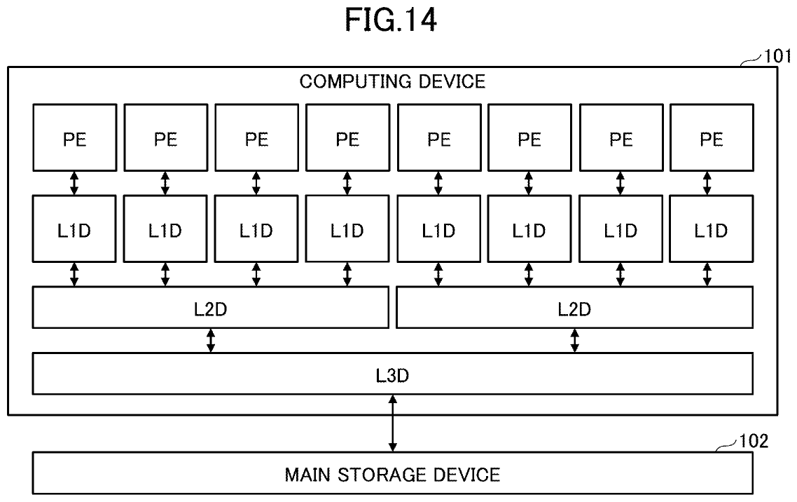

FIG. 14 is a diagram illustrating an example of a logical configuration of a computing device with hierarchical caches, and a main storage device. A computing device 101 illustrated in FIG. 14 may include a plurality of processing elements PE, a plurality of L1 data caches L1D, a plurality of L2 data caches L2D, and a L3 data cache L3D.

The plurality of L1 data caches L1D may be connected to the plurality of processing elements PE, respectively. Each L2 data cache L2D of the plurality of L2 data caches L2D may be connected to a predetermined number of L1 data caches L1D and shared by the predetermined number of processing elements PE. The L3 data cache L3D may be connected to a plurality of L2 data caches L2D and shared by all of the processing elements PE. The L3 data cache L3D may be connected to a main storage device 102, such as a DRAM or the like.

The configuration illustrated in FIG. 14 can substantially increase the bandwidth of the main storage device 102. For example, in a case where a certain processing element PE reads data Da from the main storage device 102, the data Da may remain in the L3 data cache L3D for a while. When reading the data Da from the main storage device 102, if the data Da remains in the L3 data cache L3D, other processing elements PE can acquire the data Da by accessing the L3 data cache L3D without accessing the main storage device 102.

Accordingly, by employing the hierarchical caches, the bandwidth of the main storage device 102 can be saved by reducing bandwidth usage. The saved bandwidth of the main storage device 102 can be utilized for accessing data not present in the caches, and thus, it may be regarded as if the bandwidth of the main storage device 102 is substantially increased.

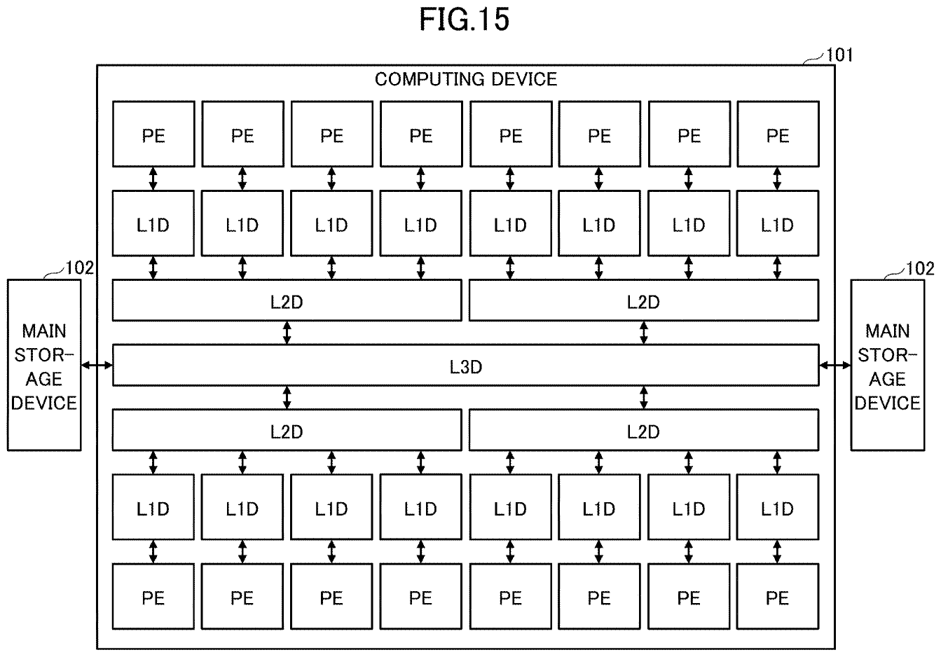

FIG. 15 is a diagram illustrating an example of a physical configuration of the computing device 101 and the main storage device 102 illustrated in FIG. 14. Cache hierarchies are not always optimal. For example, in a case where a plurality of processing elements PE continue to read mutually different data, it is meaningless to share the caches among the plurality of processing elements PE. Rather, sharing the caches may result in inefficient data movement.

As illustrated in FIG. 15, the processing elements PE and the respective memories are interconnected in an order of the processing elements PE, the L1 data caches L1D, the L2 data caches L2D, the L3 data cache L3D, and the main storage device 102. Accordingly, in a case where the processing element PE reads data from the main storage device 102, the computing device 101 sends the data read from the main storage device 102 to the L3 data cache L3D, from the L3 data cache L3D to the L2 data cache L2D, from the L2 data cache L2D to the L1 data cache L1D, and from the L1 data cache L1D to the processing element PE. In a case where data is written to the main storage device 102, the data is transferred in the reverse order to that for the case where the data is read from the main storage device 102.

In the configuration illustrated in FIG. 15, an average data movement distance is approximately the chip size of the computing device 101, specifically, will be in centimeter units. In a case where the bandwidth of the main storage device 102 is increased, it is necessary to increase each of the bandwidth between the processing element PE and the L1 data cache L1D, the bandwidth between the L1 data cache L1D and the L2 data cache L2D, and the bandwidth between the L2 data cache L2D and the L3 data cache L3D. However, it is difficult to increase the bandwidth of the main storage device 102 due to interconnect density and power consumption issues, and further, the cost increases. In contrast, in the configurations illustrated in FIG. 11 through FIG. 13, the logic die LD and the memory die MD are stacked, and thus, the distance between the dies can be set to be less than or equal to the thickness of the die. For this reason, compared to the configuration illustrated in FIG. 15, the load capacitance of the data bus connecting the logic die LD and the memory die MD can be significantly reduced, and the propagation delay time of the data signal or the like transmitted to the data bus can be significantly shortened. As a result, it is possible to improve the computational performance of the computing device 100.

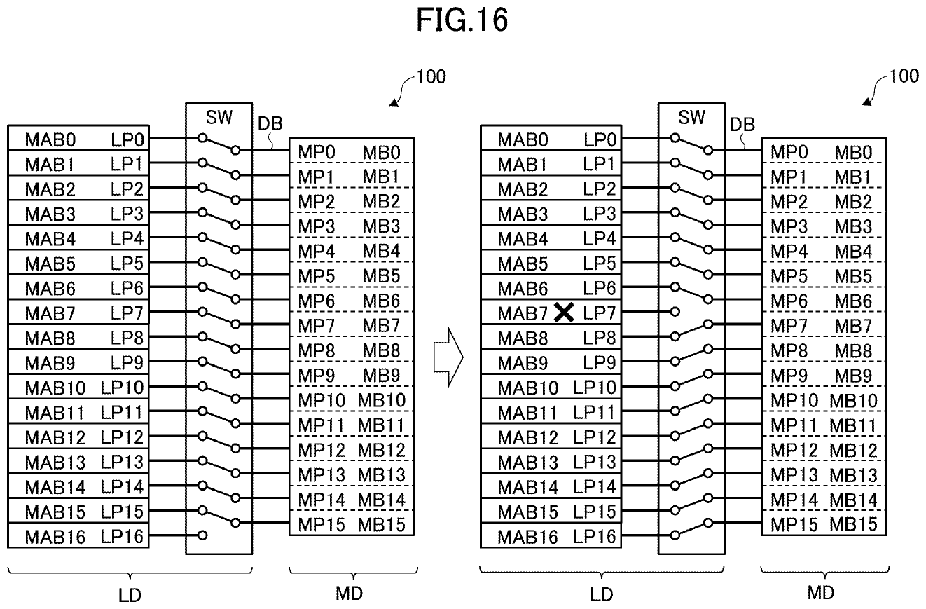

FIG. 16 is a diagram illustrating an example of redundantly placing the matrix arithmetic blocks MAB in the logic die LD of the computing device 100. In FIG. 16, each memory block MB of the computing device 100 may be allocated to each matrix arithmetic block MAB (every four processing elements PE). In a case where a large number of processing elements PE or a large number of matrix arithmetic blocks MAB are made to correspond to a large number of memory blocks MB, it is preferable to consider redundancy. In general, because a semiconductor chip manufacturing yield is not high in some cases, adding a redundant or spare circuit and switching over from a faulty circuit to the spare circuit enables defect mitigation, to thereby improve the yield.

The computing device 100 may include one matrix arithmetic block MAB16 as a spare with respect to 16 matrix arithmetic blocks MAB0 through MAB15. That is, 16 memory blocks MB may be disposed in correspondence with 17 matrix arithmetic blocks MAB0 through MAB16. The spare matrix arithmetic block MAB16 is an example of a redundant computation block.

When the matrix arithmetic blocks MAB0 through MAB15 are not faulty and the logic die LD operates normally, 16 ports LP0 through LP15 of the matrix arithmetic blocks MAB0 through MAB15 may be connected to 16 ports MP0 through MP15 of the memory blocks MB0 through MB15, respectively, via a switching circuit SW provided in the logic die LD.

For example, in a case where a failure of the matrix arithmetic block MAB7 indicated by a mark “x” is detected during a test process of the logic die LD, the connection of the switching circuit SW may be switched to disconnect the existing connection between the matrix arithmetic block MAB7 and the memory block MB7. Then, the ports LP0 through LP6 and LP8 through LP16 of the matrix arithmetic blocks MAB0 through MAB6 and MAB8 through MAB16 may be connected to the ports MP0 through MP15 of the memory blocks MB0 through MB15, respectively, via the switching circuit SW.

That is, the switching circuit SW may switchably connect the matrix arithmetic blocks MAB0 through MAB16 to the memory blocks MB0 through MB15. Accordingly, even in a case where one matrix arithmetic block of the 17 matrix arithmetic blocks MAB0 through MAB16 fails, it is possible to operate the computing device 100 in a normal manner. Hence, it is possible to improve the yield of the computing device 100.

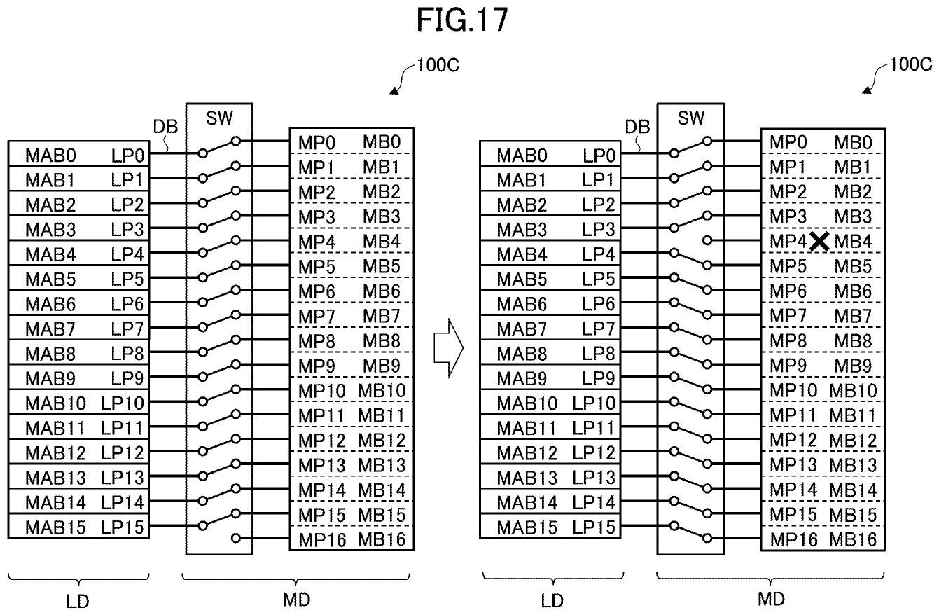

FIG. 17 is a diagram illustrating an example of redundantly placing the memory blocks MB in the memory die MD of the computing device 100. In FIG. 17, similar to FIG. 16, each memory block MB of the computing device 100 may be allocated to each matrix arithmetic block MAB (every four processing elements PE). The computing device 100 may include one memory block MB16 as a spare with respect to 16 memory blocks MB0 through MB15. That is, 17 memory blocks MB may be disposed in correspondence with 16 matrix arithmetic blocks MAB0 through MAB15. The spare memory block MB16 is an example of a redundant memory, and is an example of a redundant memory block including the redundant memory.

In a case where the memory blocks MB0 through MB15 do not fail and the memory die MD operates in a normal manner, the 16 ports MP0 through MP15 of the memory blocks MB0 through MB15 may be connected to the 16 ports LP0 through LP15 of the matrix arithmetic blocks MAB0 through MAB15, respectively, via the switching circuit SW provided in the memory die MD.

For example, in a case where a failure of the memory block MB4 indicated by a mark “x” is detected during a test process of the memory die MD, the connection of the switching circuit SW may be switched to disconnect the existing connection between the memory block MB4 and the matrix arithmetic block MAB4. The ports MP0 through MP3 and MP5 through MP16 of the memory blocks MB0 through MB3 and MB5 through MB16 may be connected to the ports LP0 through LP15 of the matrix arithmetic blocks MAB0 through MAB15, respectively, via the switching circuit SW.

That is, the switching circuit SW may switchably connect the memory blocks MB0 through MB16 to the matrix arithmetic blocks MAB0 through MAB15. Accordingly, even in a case where one memory block of the 17 memory blocks MB0 through MB16 fails, it is possible to operate the computing device 100 in a normal manner. Hence, it is possible to improve the yield of the computing device 100.

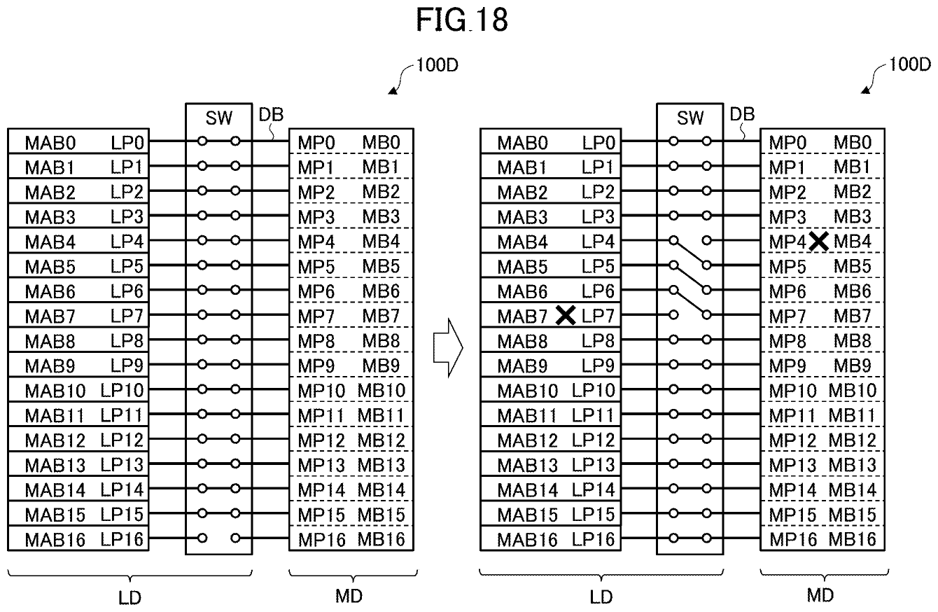

FIG. 18 is a diagram illustrating an example of redundantly placing the matrix arithmetic blocks MAB and the memory blocks MB in the computing device 100. In FIG. 18, similar to FIG. 16 and FIG. 17, each memory block MB of the computing device 100 may be allocated to each matrix arithmetic block MAB (every four processing elements PE). The computing device 100 may include 16 matrix arithmetic blocks MAB0 through MAB15, one spare matrix arithmetic block MAB16, 16 memory blocks MB0 through MB15, and one spare memory block MB16.

In a case where the matrix arithmetic blocks MAB0 through MAB15 and the memory blocks MB0 through MB15 do not fail and the logic die LD and the memory die MD operate in a normal manner, the 16 ports LP0 through LP15 of the matrix arithmetic blocks MAB0 through MAB15 may be connected to the 16 ports MP0 through MP15 of the memory blocks MB0 through MB15, respectively, via the switching circuits SW provided in the logic die LD, for example. The switching circuit SW may be provided in each of the logic die LD and the memory die MD.

For example, in a case where a failure of the matrix arithmetic block MAB7 indicated by a mark “x” is detected during the test process of the logic die LD and a failure of the memory block MB4 indicated by a mark “x” is detected during the test process of the memory die MD, the connection of the switching circuit SW may be switched. Further, in the computing device 100, the ports LP0 through LP6 and LP8 through LP16 of the matrix arithmetic blocks MAB0 through MAB6 and MAB8 through MAB16 may be connected to the ports MP0 through MP3 and MP5 through MP16 of the memory blocks MB0 through MB3 and MB5 through MB16, respectively.

Accordingly, even in a case where one matrix arithmetic block of the 17 matrix arithmetic blocks MAB0 through MAB16 and one memory block of the 17 memory blocks MB0 through MB16 fail, it is possible to operate the computing device 100 in a normal manner. Hence, it is possible to improve the yield of the computing device 100.

In the first embodiment, by connecting the plurality of processing elements PE of the logic die LD to the plurality of memory dies MD or the plurality of memory blocks MB disposed to face the logic die LD, respectively, and three-dimensionally integrating the processing elements PE and the memory dies MD or the memory blocks MB, a large memory bandwidth with low power can be obtained compared to the related art. Because a memory with a large bandwidth can be utilized with low power and at low cost, an application with relatively many memory accesses, such as training of a deep neural network, inference, scientific and technical computing, or the like can be efficiently performed with low power.

For example, the computing device 100 can set the bandwidth between the logic die LD and the memory die MD to approximately several tens of TG/s, for example. This bandwidth is sufficiently large compared to the bandwidth (256 GB/s) of HBM2 and the bandwidth (819 GB/s) of HBM3.

A second embodiment of the present disclosure is an example of a computing method for performing an inference process of a machine learning model using the computing device 100 according to the first embodiment. The computing method according to the present embodiment is not limited to the inference process of the machine learning model, and may be used for a training process of the machine learning model.

The machine learning model in the present embodiment may include a neural network. The machine learning model may include a neural network equipped with an attention (or an attention mechanism). The neural network equipped with the attention may be a neural network that is also referred to as a transformer or the like, for example. The machine learning model may include a state space model (SSM).

For example, the machine learning model may be a large language model (LLM). For example, the machine learning model may be a generative model, a foundation model, or a neural network that generates various types of data, such as audio, images, video, or the like. The machine learning model may support multimodal data.

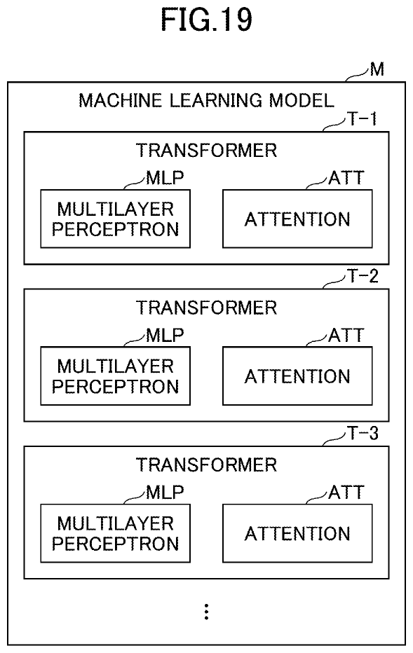

Next, a configuration of the machine learning model in the present embodiment will be described with reference to FIG. 19. FIG. 19 is a block diagram illustrating an example of the machine learning model according to the second embodiment of the present disclosure.

As illustrated in FIG. 19, a machine learning model M may include one or more transformers T (T-1, T-2, T-3, . . . ). The number of transformers T included in the machine learning model M may be an arbitrary number, and may be approximately 80, for example. The machine learning model M may include a layer, a block, a network, or the like other than the transformer T.

Hereinafter, in a case where a plurality of transformers T are present, the transformers T are represented using branch numbers, such as “transformer T-1”, “transformer T-2”, and the like when distinguishing each of the transformers T. The term “transformer T” is applied to all transformers T.

The transformer T may include a multilayer perceptron (MLP) and an attention ATT. The multilayer perceptron MLP may be a feedforward network, for example. The number of layers of the feedforward network may be an arbitrary number. The attention ATT may be a multi-head attention, for example. The number of heads of the multi-head attention may be an arbitrary number, and may be approximately 64, for example.

In the present embodiment, the number of parameters of the machine learning model M may be approximately 10 billion (B) to approximately 70 billion (B). In this case, the amount of data when quantized in an 8-bit floating-point format (FP8) is approximately 10 GB to approximately 70 GB. As an example, when 1000 tokens are generated using the machine learning model M, memory accesses of approximately 10 TB to approximately 70 TB occur. Because the bandwidth of a conventional GPU is approximately 4 TB per second, it takes approximately 2.5 seconds to approximately 17.5 seconds to generate 1000 tokens by the conventional GPU.

Further, in the present embodiment, the computing device 100 may include two blocks L2B. Each block L2B may include four blocks L1B. Each block L1B may include sixteen matrix arithmetic blocks MAB. Each matrix arithmetic block MAB may include eight processing elements PE and one matrix arithmetic unit MAU.

The matrix arithmetic block MAB may be configured in the following manner.

The local memory LM0 of the processing element PE is connected to the memory block MB. The processing element PE can read or write 16 bytes of data per cycle from or to the local memory LM0. The storage capacity of the local memory LM0 is 16 MB per processing element PE.

The local memory LM1 of the processing element PE is configured by an SRAM. The processing element PE can read or write 16 bytes of data per cycle from or to the local memory LM1. The storage capacity of the local memory LM1 is 16 KB per processing element PE.

The registers GRF0 and GRF1 of the processing element PE are configured by SRAMs. The registers GRF0 and GRF1 can read and write 16 bytes of data per cycle in parallel. The storage capacities of the registers GRF0 and GRF1 are 2 KB per processing element PE.

The register T-REG of the processing element PE is configured by a flip-flop. The register T-REG can read and write data of 16 bytes of data per cycle in parallel. The storage capacity of the register T-REG is 64 B per processing element PE.

The integer arithmetic logic unit IALU is an arithmetic unit that performs an integer addition and the like. The input to the integer arithmetic logic unit IALU is one or two 16-byte data read from the local memory LM0 or the like per cycle. The output data of the integer arithmetic logic unit IALU is 16 bytes.

The matrix arithmetic unit MAU is an arithmetic unit that performs a floating-point arithmetic. The matrix arithmetic unit MAU performs a computation of a matrix product or an element-wise multiply, accumulate, or the like of vectors. For the matrix product, the matrix arithmetic unit MAU computes the product of a 32×64 matrix and a 64×2 matrix per cycle.

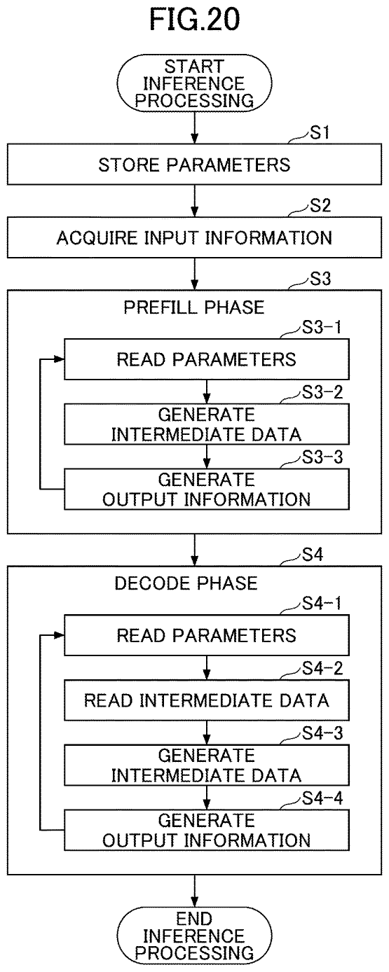

The inference process of the machine learning model in the present embodiment will be described with reference to FIG. 20. FIG. 20 is a flow chart illustrating an example of the inference process of the machine learning model M illustrated in FIG. 19. Although FIG. 20 illustrates the processing in one transformer T included in the machine learning model M, the processing of two or more transformers T included in the machine learning model M may be performed in parallel. In a case where two or more transformers T perform the processing in parallel, the transformers T may perform the processing in synchronization with one another or may perform the processing asynchronously.

In step S1, the computing device 100 stores the parameters of the machine learning model M in the memory block MB. The computing device 100 may store the parameters of the machine learning model M input from the outside in the memory block MB. The process of storing information in the memory block MB may include the computing device 100 performing at least a part of the process required for the storage.

For example, the computing device 100 may store the parameters of the machine learning model M transferred from the host memory HOSTM in response to an instruction issued by the CPU of the host 300 in the memory block MB, via the memory L2BM, the memory L1BM, and the local memory LM0. The instruction issued by the CPU of the host 300 may be a SIMD instruction. The SIMD instruction is an instruction set for processing multiple data in parallel with a single instruction. The plurality of matrix arithmetic blocks MAB included in the computing device 100 may operate in parallel according to a single SIMD instruction received from the CPU of the host 300.

The computing device 100 may store the parameters of the machine learning model M in a plurality of memory blocks MB in a distributed manner. The computing device 100 may allocate the parameters of the machine learning model M to the plurality of matrix arithmetic blocks MAB, and store some of the parameters of the machine learning model M in the memory blocks MB connected to the plurality of matrix arithmetic blocks MAB. The allocation of the parameters to the plurality of matrix arithmetic blocks MAB may be performed by the computing device 100, or may be performed by a designation from the outside, such as an instruction issued by the CPU of the host 300, for example.

In step S2, the computing device 100 acquires input information to be input to the machine learning model M. The computing device 100 may acquire input information that is input from the outside. For example, the computing device 100 may receive input information transferred from the host memory HOSTM in response to the instruction issued by the CPU of the host 300.

The input information may include text data, image data, or audio data. As an example, the text data may be a natural language sentence called a prompt. As an example, the image data may be still image data or video image data. The text data may be text data obtained by performing a speech recognition on the audio data or the video image data. The text data may be text data obtained by performing a character recognition on the image data. As an example, the image data may include a captured image of a user. As an example, the audio data may include a speech uttered by the user. The audio data may be speech-synthesized audio data generated from the text data.

The input information may be divided (or split) in units of tokens. A token is a unit of processing when a machine learning model processes electronic data, and an amount of data in one token may vary depending on a design of the machine learning model. As an example, the token is one Japanese character or one English word, but depending on a frequency of occurrence, one character may be represented by two tokens, or two or more characters may be represented by one token.

The computing device 100 may input the acquired input information to the matrix arithmetic block MAB. The computing device 100 may input a predetermined number of tokens included in the input information to the matrix arithmetic block MAB. The number of tokens input to the matrix arithmetic block MAB may be determined in advance by the design of the machine learning model M or the computing device 100. In the present embodiment, the number of tokens may be 32, for example.

The input information that is input to the matrix arithmetic block MAB may be stored in the local memory LM1 of the matrix arithmetic block MAB, or may be stored in the memory block MB connected to the matrix arithmetic block MAB. The computing device 100 may input the input information to the plurality of matrix arithmetic blocks MAB in a distributed manner. The computing device 100 may allocate the input information for the machine learning model M to the plurality of matrix arithmetic blocks MAB, and input a part of the input information to each matrix arithmetic block MAB of the plurality of matrix arithmetic blocks MAB. The allocation of the input information to the plurality of matrix arithmetic blocks MAB may be performed by the computing device 100, or may be performed by a designation from the outside, such as an instruction issued by the CPU of the host 300, for example.

In step S3, the computing device 100 performs a prefill phase. The prefill phase is a process of generating intermediate data used in the inference process of the machine learning model M, based on the input information acquired in step S2. The computing device 100 repeats computation of the multilayer perceptron MLP and computation of the attention ATT during the prefill phase. The computing device 100 may read the parameters of the machine learning model M stored in step S1 from the memory block MB, before performing the computation of the multilayer perceptron MLP or the computation of the attention ATT.

The intermediate data may differ depending on the type of the machine learning model. As an example, in a case where the machine learning model includes a transformer, the intermediate data may include a key-value cache. The key-value cache is composed of arrays of cached key vectors and value vectors. The key-value cache is generated for each layer constituting the transformer. As another example, in a case where the machine learning model includes a state space model, the intermediate data may include at least a part of states in the state space model. The state in the state space model may be represented by one or more vectors or tensors.

In step S3-1, the matrix arithmetic block MAB of the computing device 100 reads the parameters of the machine learning model M from the memory block MB. The matrix arithmetic block MAB may read at least some of the parameters of the machine learning model M stored in the memory block MB. The matrix arithmetic block MAB may read only the parameters corresponding to the input information that is input in step S2. The matrix arithmetic block MAB may read only the parameters to be used in subsequent step S3-2 or S3-3.

The matrix arithmetic block MAB may read at least some of the parameters of the machine learning model M from the memory block MB during the processing of step S3-2 or S3-3. As an example, during the processing of step S3-2 or S3-3 for a part of the input information, the matrix arithmetic block MAB may read the parameters to be used in step S3-2 or S3-3 for a subsequent, other part of the input information.

In step S3-2, the matrix arithmetic block MAB of the computing device 100 generates intermediate data. The matrix arithmetic block MAB may generate the intermediate data by computing the attention ATT of the machine learning model M. The matrix arithmetic block MAB may generate intermediate data corresponding to input information that is input in step S2. The matrix arithmetic block MAB may generate the intermediate data using the parameters read in step S3-1.

The matrix arithmetic block MAB may store the generated intermediate data in the memory block MB. The matrix arithmetic block MAB may store at least a part of the intermediate data in the memory block MB. The matrix arithmetic block MAB may store the intermediate data in the memory block MB connected to the matrix arithmetic block MAB.

In step S3-3, the matrix arithmetic block MAB of the computing device 100 generates output information to be output from the machine learning model M. The matrix arithmetic block MAB may generate the output information by computing the multilayer perceptron MLP of the machine learning model M. The matrix arithmetic block MAB may generate the output information using the parameters read in step S3-1. The matrix arithmetic block MAB may generate the output information using the intermediate data generated in step S3-2.

The output information may include at least one of text data, audio data, or image data. The image data may include a still image or a video image, and the video image may include audio data. The output information may be multimodal data including at least two of text data, audio data, or image data. The output information may be divided (or split) into units of tokens. The output information may be one token that is output with respect to a last token included in the input information.

The matrix arithmetic block MAB may store the generated output information. The matrix arithmetic block MAB may store the output information in the local memory LM1 of the matrix arithmetic block MAB, or may store the output information in the memory block MB connected to the matrix arithmetic block MAB. The matrix arithmetic block MAB may store only the output information that is generated when the processing of the input information that is input in the step S2 is completed, in the local memory LM1 or the memory block MB.

The matrix arithmetic block MAB may repeat the processing from step S3-1 to step S3-3, or may perform the processing from step S3-1 to step S3-3 only once, and perform the processing of step S4. The matrix arithmetic block MAB may repeat the processing from step S3-1 to step S3-3 until the processing of the input information that is input in step S2 is completed. The matrix arithmetic block MAB may read all of the parameters stored in the memory block MB in step S3-1, and repeat only the processing of steps S3-2 and S3-3. As an example, in a case where the input information having a large size is input in step S2, the input information may be divided (or split) into a plurality of pieces of information, and the processing from step S3-1 to step S3-3 may be repeated for each of the divided pieces of information of the input information.

In step S4, the computing device 100 performs a decode phase. The decode phase is a process of generating the output information of the machine learning model M using the intermediate data generated during the prefill phase. The computing device 100 repeats the computation of the multilayer perceptron MLP and the computation of the attention ATT during the decode phase. The computing device 100 may read the parameters of the machine learning model M stored in step S1 from the memory block MB before performing the computation of the multilayer perceptron MLP and the computation of the attention ATT.

In step S4-1, the matrix arithmetic block MAB of the computing device 100 reads the parameters of the machine learning model M from the memory block MB. The matrix arithmetic block MAB may read at least some of the parameters of the machine learning model M stored in the memory block MB. The matrix arithmetic block MAB may read only the parameters corresponding to the input information that is input in the step S2. The matrix arithmetic block MAB may read only the parameters to be used in subsequent step S4-3 or S4-4. The matrix arithmetic block MAB may sequentially read at least some of the parameters of the machine learning model M stored in the memory block MB at a timing required for the processing.

The matrix arithmetic block MAB does not need to read the parameters that were read during the prefill phase. In a case where all of the parameters are read during the prefill phase, the matrix arithmetic block MAB does not need to perform the processing of step S4-1.

In step S4-2, the matrix arithmetic block MAB of the computing device 100 reads the intermediate data from the memory block MB. The matrix arithmetic block MAB may read at least a part of the intermediate data stored in the memory block MB. The matrix arithmetic block MAB may read all of the intermediate data stored in the memory block MB. The matrix arithmetic block MAB may read at least one of the intermediate data generated during the prefill phase or the intermediate data generated during the decode phase. The matrix arithmetic block MAB may read at least a part of the intermediate data generated during the prefill phase. The matrix arithmetic block MAB may read at least a part of the intermediate data generated during the decode phase. The matrix arithmetic block MAB may read at least a part of new intermediate data generated during a past decode phase performed in the past. The matrix arithmetic block MAB may sequentially read at least a part of the intermediate data stored in the memory block MB at a timing required for the processing.

In step S4-3, the matrix arithmetic block MAB of the computing device 100 generates intermediate data. The matrix arithmetic block MAB may generate the intermediate data by computing the attention ATT of the machine learning model M. The matrix arithmetic block MAB may generate intermediate data corresponding to output information that is generated during the prefill phase. The matrix arithmetic block MAB may generate intermediate data corresponding to output information generated during the decode phase. The matrix arithmetic block MAB may generate the intermediate data using the parameters read in step S4-1.

The matrix arithmetic block MAB may generate new intermediate data using the intermediate data read in step S4-2. The matrix arithmetic block MAB may generate the new intermediate data using at least a part of the intermediate data generated during the prefill phase. The matrix arithmetic block MAB may generate the new intermediate data using at least a part of the intermediate data generated during the decode phase. The matrix arithmetic block MAB may generate the new intermediate data using at least a part of the intermediate data generated during the prefill phase and at least a part of the intermediate data generated during the decode phase.

The matrix arithmetic block MAB may store the generated, new intermediate data in the memory block MB. The matrix arithmetic block MAB may store at least a part of the new intermediate data in the memory block MB. The matrix arithmetic block MAB may store the new intermediate data in the memory block MB connected to the matrix arithmetic block MAB. At least a part of the intermediate data stored in the memory block MB may be read during a next decode phase to be performed next.

In step S4-4, the matrix arithmetic block MAB of the computing device 100 generates output information to be output from the machine learning model M. The matrix arithmetic block MAB may generate the output information by computing a multilayer perceptron MLP of the machine learning model M. The matrix arithmetic block MAB may generate the output information using the parameters read in step S4-1. The matrix arithmetic block MAB may generate the output information using the intermediate data read in step S4-2 and the intermediate data generated in step S4-3.

The matrix arithmetic block MAB may store the generated output information. The matrix arithmetic block MAB may store the output information in the local memory LM1 of the matrix arithmetic block MAB, or may store the output information in the memory block MB connected to the matrix arithmetic block MAB.

The matrix arithmetic block MAB may output the generated output information. The matrix arithmetic block MAB may output the output information including a predetermined number of tokens. The matrix arithmetic block MAB may output the output information at predetermined time intervals. The output information that is output from the matrix arithmetic block MAB may be output to the outside of the computing device 100. As an example, the output information may be transferred to the host memory HOSTM.

The matrix arithmetic block MAB may repeat the processing from step S4-1 to step S4-4. The matrix arithmetic block MAB may repeat the processing from step S4-1 to step S4-4 until a predetermined condition is satisfied. As an example, the matrix arithmetic block MAB may repeat the processing from step S4-1 to step S4-4 until information (or end-of-output information) indicating an end of the output information is generated in step S4-4. The end-of-output information of the output information may be an end-of-sequence token (EOS token), for example. As another example, the matrix arithmetic block MAB may repeat the processing of steps S4-1 to S4-4 until the number of repetitions reaches a predetermined number. The matrix arithmetic block MAB may read all of the parameters stored in the memory block MB in step S4-1 and repeat only the processing from step S4-2 to step S4-4.

As another example, the computing device 100 may perform a decode phase of a state space model. The computing device 100 may input the last token generated during the prefill phase to the state space model. The state space model may read the state of the state space model stored in the memory block MB, and perform a forward processing with respect to the input token. The state space model may generate a token following the input token, and update the state of the state space model. The computing device 100 may acquire the token output by the state space model as the output information. The computing device 100 may overwrite the state stored in the memory block MB with the state of the updated state space model.

### Computation of Multilayer Perceptron

The computation of the multilayer perceptron MLP will be described in more detail. As an example, the computation of the multilayer perceptron MLP during the decode phase will be described.

In the present embodiment, the multilayer perceptron MLP is defined by formulas (1) and (2), where x denotes input information of a 32×8192 matrix, Wᵤₚ denotes a parameter of a 8192×32768 matrix, W_{down} denotes a parameter of a 32768×8192 matrix, and f denotes an activation function.

y=x·Wᵤₚ (1)

z=x+f(y)·W_{down} (2)

However, the activation function f may be a ReLU function or a SiLU function. The ReLU function may be a function defined by a formula (3). The SiLU function may be a function defined by a formula (4).

ReLU(x)=x if x>0 else 0 (3)

SiLU(x)=x/(1+exp(−x)) (4)

The computation of the multilayer perceptron MLP is characterized in that one input in the computation of the matrix product is a wide matrix, such as a 32×8192 matrix. The value “32” in the wide matrix corresponds to a batch size. A small batch size has advantages, such as a lower token-to-token latency, a reduced amount of memory usage, or the like.

Conventional processors cannot compute such a matrix product at a high speed. This is because the size of the parameters Wᵤₚ and W_{down} is large with respect to the amount of computation, and thus, the speed of reading the parameters Wᵤₚ and W_{down} from the memory is slower than the computational speed.

The computing device 100 achieves a high-speed reading of the parameters Wᵤₚ and W_{down}. In the computing device 100, the plurality of matrix arithmetic blocks MAB share and compute the matrix product.

As an example, a product x·Wᵤₚ of the input information x and the parameter Wᵤₚ may be computed in divisions by 96 matrix arithmetic blocks MAB in the following manner. The input information x is a 32×8192 matrix. The parameter Wᵤₚ is a 8192×32768 matrix.

Two blocks L2B per logic die LD redundantly hold the input information x. The two blocks L2B each hold a parameter Wᵤₚ^{(1,2)} obtained by dividing (or splitting) the parameter Wᵤₚ into two parts in a column direction. The parameter Wᵤₚ^{(1,2)} is a 8192×16384 matrix.

The product x·Wᵤₚ can be computed by performing the following processes (1) and (2) in parallel. In this example, it is assumed that a 0th block L2B[0] holds a parameter Wᵤₚ^{(1,2)}₀, and a first block L2B[1] holds a parameter Wᵤₚ^{(1,2)}₁.

(1) The block L2B[0] computes a matrix product x·Wᵤₚ^{(1,2)}₀ of the input information x and the parameter Wᵤₚ^{(1,2)}₀. A result of this computation is a 32×16384 matrix.

(2) The block L2B[1] computes a matrix product x·Wᵤₚ^{(1,2)}₁ of the input information x and the parameter Wᵤₚ^{(1,2)}₁. A result of this computation is a 32×16384 matrix.

The four blocks L1B per block L2B redundantly hold the input information x. The four blocks L1B each hold a parameter Wᵤₚ^{(1,8)} obtained by dividing the parameter Wᵤₚ^{(1,2)} into four parts in the column direction. The parameter Wᵤₚ^{(1,8)} is a 8192×4096 matrix.

The 16 matrix arithmetic blocks MAB per block L1B each hold input information x^{(1,4)} obtained by dividing the input information x into four parts in the column direction. The input information x^{(1,4)} is a 32×2048 matrix. Further, the 16 matrix arithmetic blocks MAB each hold a parameter Wᵤₚ^{(4,32)} obtained by dividing the parameter Wᵤₚ^{(1,8)} into four parts in both the row and column directions. The parameter Wᵤₚ^{(4,32)} is a 2048×1024 matrix.

The 16 matrix arithmetic blocks MAB each compute a matrix product x^{(1,4)}·Wᵤₚ^{(4,32)} of the input information x^{(1,4)} and the parameter Wᵤₚ^{(4,32)}. A result of this computation is a 32 ×1024 matrix.

Subsequently, the computing device 100 divides (or partitions) the 16 matrix arithmetic blocks MAB per block L1B into groups each including four matrix arithmetic blocks MAB. The computing device 100 adds the computation results x^{(1,4)}·Wᵤₚ^{(4,32)} of the matrix arithmetic blocks MAB for each group. Because there are four groups, the computation result x·Wᵤₚ^{(1,8)} is a 32×4096 matrix. The computing device 100 may store the computation result x·Wᵤₚ^{(1,8)} in the memory L1BM.

The computing device 100 arranges and combines the computation results x·Wᵤₚ^{(1,8)} of the eight blocks L1B. The computation result x·Wᵤₚ is a 32×32768 matrix. The computing device 100 may divide the computation result x·Wᵤₚ and store the divided result in the memory block MB connected to each matrix arithmetic block MAB for subsequent computation of the matrix product.

As another example, the product x·W_{down} of an output f(y) of the activation function f and the parameter W_{down} may be computed in divisions by 96 matrix arithmetic blocks MAB in the following manner. The output f(y) of the activation function f is a 32×32768 matrix. The parameter W_{down} is a 32768×8192 matrix.

Two blocks L2B per logic die LD each hold an output y^{(1,2)} obtained by dividing the output f(y) of the activation function f into two parts in the column direction. The output y^{(1,2)} is a 32×16384 matrix. Further, the two blocks L2B each hold a parameter W_{down}^{(2,1)} obtained by dividing the parameter W_{down} into two parts in a row direction. The parameter W_{down}^{(2,1)} is a 16384×8192 matrix.

Four blocks L1B per block L2B each hold an output y^{(1,8)} obtained by dividing the output y^{(1,2)} into four parts in the column direction. The output y^{(1,8)} is a 32×4096 matrix. The four blocks L1B each hold a parameter W_{down}^{(8,1)} obtained by dividing the parameter W_{down}^{(2,1)} into four parts in the row direction. The parameter W_{down}^{(8,1)} is a 4096×8192 matrix.

The 16 matrix arithmetic blocks MAB per block L1B each hold an output y^{(1,32)} obtained by dividing the output y^{(1,8)} into four parts in the column direction. The output y^{(1,32)} is a 32×1024 matrix. Further, the 16 matrix arithmetic blocks MAB each hold a parameter W_{down}^{(32,4)} obtained by dividing the parameter W_{down}^{(8,1)} into four parts in both the row and column directions. The parameter W_{down}^{(32,4)} is a 1024×2048 matrix.

The 16 matrix arithmetic blocks MAB each compute a matrix product y^{(1,32)}·W_{down}^{(32,4)} of the output y^{(1,32)} and the parameter W_{down}^{(32,4)}. A result of this computation is a 32×2048 matrix.

Subsequently, the computing device 100 divides the 16 matrix arithmetic blocks MAB per block L1B into groups each including four matrix arithmetic blocks MAB. The computing device 100 adds the computation results y^{(1,32)}·W_{down}^{(32,4)} of the matrix arithmetic blocks MAB for each group. Because there are four groups, the computation result y^{(1,8)}·W_{down}^{(8,1)} is a 32×8192 matrix. The computing device 100 may store the computation result y^{(1,8)}×W_{down}^{(8,1)} in the memory L1BM.

Four blocks L1B per block L2B add the computation results y^{(1,8)}·W_{down}^{(8,1)} of the 16 matrix arithmetic blocks MAB. A computation result y^{(1,2)}·W_{down}^{(2,1)} is a 32×8192 matrix. The computing device 100 may store the computation result y^{(1,2)}·W_{down}^{(2,1)} in the memory L2BM.

Two blocks L2B per logic die LD add the computation results y^{(1,2)}·W_{down}^{(2,1)}of the four blocks L1B. A computation result y·W_{down} is a 32×8192 matrix. The computing device 100 may divide one or both of the computation results y·W_{down} of the two blocks L2B and store the divided result in the memory block MB connected to each matrix arithmetic block MAB for subsequent computation of the matrix product.

The above-described computations may be performed in series or in parallel. For example, summations may be performed in parallel after the computations of the matrix products are partially completed. For example, if the computation of the matrix product is completed in a plurality of blocks L1B, the summations of the matrices as the computation results may be performed.

The above-described processing is an outline of the process of computing the matrix product using the computing device 100. Because the amount of data of the parameters Wᵤₚ and W_{down} of the machine learning model M is large, in the present embodiment, the parameters Wᵤₚ and W_{down} are divided and allocated to the plurality of matrix arithmetic blocks MAB of the computing device 100, and are stored in the memory blocks MB connected to the respective matrix arithmetic blocks MAB. In the present embodiment, each matrix arithmetic block MAB divides the parameters Wᵤₚ and W_{down} without duplication. This enables the computing device 100 to read the parameters of the machine learning model M from the memory block MB at a high speed.

The matrix product x^{(1,4)}·Wᵤₚ^{(4,32)} computed by the matrix arithmetic block MAB during the computation of the matrix product x·Wᵤₚ will be described in more detail. The input information x^{(1,4)} is a 32×2048 matrix. The parameter Wᵤₚ^{(4,32)} is a 2048×1024 matrix.

The matrix arithmetic block MAB includes a register called a matrix register. As an example, the matrix register may be included in the matrix arithmetic unit MAU included in the matrix arithmetic block MAB. In the present embodiment, the matrix register can store a 32×64 matrix. First, the matrix arithmetic block MAB writes one 32×64 matrix M for which a product is to be computed into the matrix register. Next, the matrix arithmetic block MAB inputs a 64×2 matrix B and a 32×2 matrix C of the other matrix for which the product is to be computed to the matrix register. The 32×2 matrix C is also called an “accumulator”. The matrix register computes D=M·B+C, and outputs a 32×2 matrix D. The matrices M and B may be quantized to FP8. The matrices C and D may be quantized to FP16.

The computation using the matrix register is performed once by each matrix arithmetic block MAB per cycle. As an example, a method of computing a matrix product of 64×64 matrices will be described. Two matrices for which the product is to be computed are denoted by A and B, respectively.

The following description introduces a notation that uses subscripts to denote submatrices. A_{i:j:k:l} is a (j−i)×(l−k) matrix obtained by extracting the i-th to j−1-th rows and the k-th to l−1-th columns of the matrix A. As an example, A_{0:32,0:64} is a submatrix obtained by extracting an upper half of the matrix A. A_{0:32,0:32} is a submatrix obtained by extracting an upper left half of the matrix A.

First, the matrix arithmetic block MAB writes the submatrix A_{0:32,0:64} to the matrix register. Next, the matrix arithmetic block MAB computes the following formula (5) for an integer i of 0 or more and 31 or less, where “0” denotes a zero matrix.

C_{0:32,2i:(i+1)}=A_{0:32,0:64}·B_{0:64,2i:(i+1)}+0 (5)

Next, the matrix arithmetic block MAB writes the submatrix A_{32:64,0:64} to the matrix register. Next, the matrix arithmetic block MAB computes the following formula (6) for an integer i of 0 or more and 31 or less.

C_{32:64,2i:(i+1)}=A_{32:64,0:64}·B_{0:64,2i:(i+1)}+0 (6)

Accordingly, the computing of the product of the 64×64 matrices is completed. When the matrices are larger than the 64×64 matrices, a previous computation result may be input in place of the zero matrix.

In a large language model (LLM) as an example of the machine learning model M, the processes of writing a matrix (x, y, or the like described above) called activation into the matrix register and writing 64×2 parameters for each of the parameters Wᵤₚ and W_{down} into the matrix register per cycle are performed. The computing device 100 can read the parameters Wᵤₚ and W_{down} from the memory block MB at a high speed. Hence, the inference process of the machine learning model M can be performed at a high speed using the computing device 100.

In a case where the inference process of the machine learning model M is performed using the computing device 100, the data movement among the matrix arithmetic blocks MAB can be reduced by appropriately dividing the parameters of the machine learning model M. The computing device 100 is configured such that each processing element PE of the plurality of processing elements PE can treat the memory block MB as a local memory. For this reason, by storing the parameters used by the processing elements PE in the memory blocks MB connected to the processing elements PE, respectively, the inference process of the machine learning model M can be performed at a high speed.

The computation of the multilayer perceptron MLP during the decode phase is as described above. In the computation of the multilayer perceptron MLP during the decode phase, the input information x is a 32×8192 matrix, and the number of rows, 32 is the batch size. On the other hand, in the computation of the multilayer perceptron MLP during the prefill phase, the computation may be performed with a predetermined number of tokens as the unit of processing for one piece of input information (in other words, for a batch size 1). That is, in the computation of the multilayer perceptron MLP during the decode phase, the number of rows, 32 of the input information x corresponds to the batch size, but in the computation of the multilayer perceptron MLP during the prefill phase, the number of rows, 32 of the input information x corresponds to the number of tokens input to the machine learning model M.

### Computation of Attention

The computation of the attention ATT will be described in more detail. As an example, the computation of the multilayer perceptron MLP during the decode phase will be described.

The computation of the attention ATT may include a part similar to the computation of the multilayer perceptron MLP, and a part that computes a core attention. The part that computes the core attention may include a process of computing the key-value cache. Hereinafter, a description of the part similar to the computation of the multilayer perceptron MLP will be omitted.

In the present embodiment, the attention ATT receives a query vector Q, a key vector K, and a value vector V as inputs. The query vector Q is a 32×8192 matrix. The key vector K is a 32×L×1024-dimensional vector, and the value vector V is a 32×L×1024-dimensional vector, where L is an integer called a context length. That is, the key vector K and the value vector V both have dimensions 32×L×1024. The context length L is incremented by one each time the machine learning model M infers one token. Accordingly, in the computation of the attention ATT, it is necessary to configure the attention ATT to be able to cope with various context lengths L.

The computing device 100 divides (or partitions) each of the query vector Q, the key vector K, and the value vector V input to the attention ATT into 64 heads. As an example, the computing device 100 divides the query vector Q into 64 to obtain 64 32×128 matrices q. The computing device 100 allocates the 64 matrices q to 64 heads. The computing device 100 divides the key vector K into eight to obtain eight 32×L×128 tensors k. The computing device 100 duplicates eight tensors k, and allocates the eight tensors k to 64 heads. Furthermore, the computing device 100 divides the value vector V into eight 32×L×128 tensors v, duplicates eight tensors v, and allocates the eight tensors v to 64 heads.

In the following, the matrices q, tensors k, and tensors v allocated to the heads may be regarded as 32 128-dimensional column vectors q′ having a dimension 128, L×128-dimensional tensors k′ having dimensions L×128, and L×128-dimensional tensors v′ having dimensions L×128, respectively. The computing device 100 computes the following formula (7) for 32 vectors q′, tensors k′, and tensors v′.

Softmax(q′(k′)^{T})v′ (7)

In the formula (7), “^{.T}(superscript T)” indicates transposition. Hereinafter, the notation of the Softmax function will be omitted.

At the primitive level, the computation of the core attention reduces to a product of a 8×128 matrix and a 128×L matrix, and a product of a 8×L matrix and a L×128 matrix per eight heads. Because the context length L is usually larger than 8, the speed of reading the 128×L matrix and the L×128 matrix from the memory block MB becomes a bottleneck. But if the query vector Q, the key vector K, and the value vector V are divided (or partitioned) appropriately, the speed of reading can be increased as in the computation of the multilayer perceptron MLP. In this example, because the key vector K and the value vector V are 32×L×1024 tensors, respectively, and the query vector Q is a 32×8192 matrix, a division (or a partitioning) with emphasis on the key vector K and the value vector V having the larger sizes is performed.

Two blocks L2B per logic die LD each hold a tensor K^{(1,1,2)} obtained by dividing the key vector K into two parts. The tensor K^{(1,1,2)} is a 32×L×512 tensor. The two blocks L2B each hold a tensor V^{(1,1,2)} obtained by dividing the value vector V into two parts. The tensor V^{(1,1,2)} is a 32×L×512 tensor. Further, the two blocks L2B each hold a matrix Q^{(1,2)} obtained by dividing the query vector Q into two parts. The matrix Q^{(1,2)} is a 32×4096 matrix.

Four blocks L1B per block L2B hold the tensor K^{(1,1,8)} obtained by dividing the tensor K^{(1,1,2)} into four parts. The tensor K^{(1,1,8)} is a 32×L×128 tensor. The four blocks L1B each hold a tensor V^{(1,1,8)} obtained by dividing the tensor V^{(1,1,2)} into four parts. The tensor V^{(1,1,8)} is a 32×L×128 tensor. Further, the four blocks L1B each hold a matrix Q^{(1,8)} obtained by dividing the matrix Q^{(1,2)} into four parts. The matrix Q^{(1,8)} is a 32×1024 matrix.

The 16 matrix arithmetic blocks MAB per block L1B each hold a tensor K^{(1,16,8)} obtained by dividing the tensor K^{(1,1,8)} into 16 parts. The tensor K^{(1,16,8)} is a 32×(L/16)×128 tensor. Further, the 16 matrix arithmetic blocks MAB each hold a tensor V^{(1,16,8)} obtained by dividing the tensor V^{(1,1,8)} into 16 parts. The tensor V^{(1,16,8)} is a 32×(L/16)×128 tensor. Further, the 16 matrix arithmetic blocks MAB each hold duplicated copies of a matrix Q^{(1,8)}.

The four blocks L1B each repeat following processes (1) to (6) 32 times.
(1) The block L1B extracts one row (that is, a 1024-dimensional vector) from the 32×1024 matrix Q^{(1,8)}. The block L1B regards the extracted vector having a dimension 1024 as an 8×128 matrix q.
(2) The block L1B extracts the L×128 matrix k corresponding to the matrix q from the 32×L×128 tensor K^{(1,1,8)}.
(3) The block L1B computes q@k^{T} to obtain an 8×L matrix t.
(4) The block L1B computes the Softmax function for each row of the matrix t, and regards the result as s.
(5) The block L1B extracts an L×128 matrix v corresponding to the matrix q from the 32×L×128 tensor V^{(1,1,8)}.
(6) The block L1B computes s@v to obtain an 8×128 matrix. The block L1B regards an 8×128 matrix as a vector having a dimension 1024.

The four blocks L1B each combine the 32 vectors having the dimension 1024 obtained by repeating the processes (1) to (6) 32 times, thereby obtaining a 32×1024 matrix. Because the computing device 100 includes eight blocks L1B in the logic die LD, eight 32×1024 matrices are obtained in total. The computing device 100 combines the eight 32×1024 matrices to obtain a 32×8192 matrix. The 32×8192 matrix obtained in this manner corresponds to a computation result of the core attention.

In the computation of the block L1B, the matrix arithmetic block MAB in the block L1B repeats the following processes (1) to (8) 32 times.
(1) The 16 matrix arithmetic blocks MAB each hold duplicate copies of a 8×128 matrix q.
(2) The matrix arithmetic blocks MAB each write an 8×64 matrix, which is a lower half of the matrix q, into the matrix register.
(3) The memory block MB stores a (L/16) ×128 matrix k. The matrix arithmetic block MAB reads a 2×64 matrix per cycle from the matrix k, and computes a product with the lower half of the matrix q. A result of this computation is an 8×(L/16) matrix. This computation takes L/32 cycles.
(4) The matrix arithmetic block MAB writes an 8×64 matrix, which is an upper half of the matrix q, into the matrix register.
(5) The matrix arithmetic block MAB computes a product of the matrix k and the upper half of the matrix q in the same manner as in the process (3). A result of this computation is an 8×(L/16) matrix. The matrix arithmetic block MAB accumulates the two 8×(L/16) matrices. The computation of the processes (2) to (5) may be performed by accumulating the matrix products after the matrix products are computed, or may be performed simultaneously by a matrix multiplication-and-accumulation operation.
(6) The matrix arithmetic block MAB computes a Softmax function for each row of the 8×(L/16) matrix, and regards a result of this computation as s. In this state, the matrix arithmetic block MAB needs to communicate with another matrix arithmetic block MAB in the same block L1B.
(7) The matrix arithmetic block MAB computes an 8×(L/16) matrix s and an (L/16)×128 matrix v. Specifically, the matrix arithmetic block MAB repeats the following process ceil (L/1024) times. First, a 8×64 portion of the matrix s is written to the matrix register. Next, a 64×2 portion of the matrix v is read from the memory block MB per cycle, and input to the matrix register. In this state, the accumulation is performed appropriately. As a result, an 8×128 matrix is obtained.
(8) The 16 matrix arithmetic blocks MAB each regard the 8×128 matrix as a vector having a dimension 1024, and perform a summation.

As a result of repeating the processes (1) to (8) 32 times, the block L1B obtains a 32×1024 matrix. The computing device 100 obtains a 32×8192 matrix as a whole.

In the computation of the block L1B, it is important that the matrix k and the matrix v are read in parallel from each matrix arithmetic block MAB. When the matrix k and the matrix v are appropriately divided (or partitioned) and stored in the memory block MB, the above-described computation procedure can be achieved. The method of dividing (or partitioning) the matrix k and the matrix v can be naturally derived from the above-described computation procedure. That is, the two blocks L2B perform channel-wise division (or partitioning) of the matrix k and the matrix v, the four blocks L1B in each block L2B perform the channel-wise division, and the 16 matrix arithmetic blocks MAB in the block L1B divide the context length L.

The matrix k and the matrix v are generated each time a new token is inferred, and may be written to an appropriate memory block MB each time. For example, in a case where a vector k having a dimension 1024 is generated, vectors having a dimension 128 obtained by dividing the vector k into eight parts may be allocated to eight blocks L1B, respectively. In a case where the matrix k corresponds to an nth token, the vector having a dimension 128 may be allocated to the matrix arithmetic block MAB corresponding to a remainder when n is divided by 16. The matrix arithmetic block MAB may write the vector having the dimension 128 allocated to the matrix arithmetic block MAB to the memory block MB connected to the matrix arithmetic block MAB.

The computation of the attention ATT during the decode phase is as described above. Hereinafter, as another example, the computation of the attention ATT during the prefill phase will be described. The computation of the attention ATT during the prefill phase will be described by focusing on the difference from the computation of the attention ATT during the decode phase. Unless indicated otherwise, the computation of the attention ATT during the prefill phase may be configured similarly to the computation of the attention ATT during the decode phase.

The computation of the attention ATT during the prefill phase differs from the computation of the attention ATT during the decode phase on the following points.
(1) A 32×8192 matrix q is regarded as a 32×8×8×128 tensor.
(2) Eight blocks L1B per logic die LD are associated with 32×8×128 tensors obtained by dividing the 32×8×8×128 tensors into eight parts.
(3) The 16 matrix arithmetic blocks MAB in the block L1B each hold duplicate copies of the 32×8×128 tensor.
(4) The matrix arithmetic block MAB repeats the following processes <1> to <7> eight times.
<1> The matrix arithmetic block MAB writes a 32×64 matrix, which is the lower half of the matrix q, into the matrix register.
<2> The memory block MB stores a (L/16)×128 matrix k. The matrix arithmetic block MAB reads a 2×64 matrix per cycle from the matrix k, and computes a product with the lower half of the matrix q. A result of this computation is a 32×(L/16) matrix. This computation takes L/8 cycles.
<3> The matrix arithmetic block MAB writes a 32×64 matrix, which is the upper half of the matrix q, into the matrix register.
<4> The matrix arithmetic block MAB computes a product of the matrix k and the upper half of the matrix q in the same manner as in the process <2> . A result of this computation is a 32×(L/16) matrix. The matrix arithmetic block MAB accumulates the two 32×(L/ 16) matrices. The computation of the processes <1> to <4> may be performed by accumulating the matrix products after the matrix products are computed, or may be performed simultaneously by a matrix multiplication-and-accumulation operation.
<5> The matrix arithmetic block MAB computes a Softmax function for each row of the 32×(L/16) matrix, and regards a result of this computation as s. In this state, the matrix arithmetic block MAB needs to communicate with another matrix arithmetic block MAB in the same block L1B.
<6> The matrix arithmetic block MAB computes a 32×(L/16) matrix s and a (L/16)×128 matrix v. Specifically, the matrix arithmetic block MAB repeats the following process ceil (L/1024) times. First, a 32×64 portion of the matrix s is written to the matrix register. Next, a process of reading a 64×2 portion of the matrix v from the memory block MB per cycle and inputting the read portion 64×2 of the matrix v to the matrix register is repeated 64 times. In this state, the accumulation is performed appropriately. As a result, a 32×128 matrix is obtained.
<7> The 16 matrix arithmetic blocks MAB each regard the 32×128 matrix as a vector having a dimension 4096, and perform a summation.

As a result of repeating the processes <1> to <7> eight times, the block L1B obtains a 32×1024 matrix. The computing device 100 obtains a 32×8192 matrix as a whole.

The matrix arithmetic block MAB may perform the prefill phase of the step S3 and the decode phase of the step S4 in parallel. In other words, while the matrix arithmetic block MAB is performing the prefill phase in some batches, the matrix arithmetic block MAB may perform the decode phase in other batches.

As an example, it is assumed that the batch size of the matrix arithmetic block MAB is 17, 16 prefill phases are completed, and one prefill phase is incomplete. In this case, the matrix arithmetic block MAB may perform 16 decode phases and one prefill phase in parallel. Specifically, the matrix arithmetic block MAB may input a total of 32 tokens, that is, 16 tokens in one prefill phase and one token in each of the 16 decode phases, to the machine learning model M. In the computation of the core attention, the matrix arithmetic block MAB may perform the computation of the decode phase with the batch size of 16, and perform the computation of the prefill phase with 16 tokens.

The Softmax function may be configured as follows to compute the core attention of an Lth token.

Softmax ((q of Lth token)@(k of 1st to Lth tokens)^{T} @(v of 1st to Lth tokens))

By performing the inference process of the machine learning model using the computing device 100, a throughput of the inference process of the machine learning model can be improved, for example. The throughput may include a throughput per user (for example, the number of tokens that can be processed per second) or a throughput per cost (for example, the number of tokens that can be processed per currency unit), for example.

The throughput per user is a throughput as viewed from the user. As an example, an information processing system that interacts with the user using the machine learning model is considered. In such an information processing system, an output of a response is started after all inputs from the user are received, and the response may be displayed intermittently on a screen. The throughput per user may be regarded as being a speed at which the responses are displayed on the screen.

The throughput per user is mainly determined by the following factors.
A memory bandwidth and a capacity of a processor.
A level or degree of tensor parallelism.
A bandwidth of a network used for the tensor parallelism.
A batch size.

The batch size may be appropriately determined when designing the information processing system. In a case where the batch size is appropriately determined and the bandwidth of the network is sufficient, the throughput per user depends on a time required to read the parameters of the machine learning model from the memory. For example, the throughput per user is proportional to the speed of reading the parameters of the machine learning model from the memory.

The use of the computing device 100 enables the speed of reading the parameters of the machine learning model to be increased. Further, by reading the parameters of the machine learning model in parallel by the tensor parallelism or the like, the throughput per user can be greatly improved. For example, a throughput per die can be improved to approximately five times to approximately ten times that of a general purpose graphics processing unit (GPGPU) including a high bandwidth memory (HBM). As a result, a cost per die can be reduced to approximately one fifth that of such a GPGPU.

Moreover, according to the present embodiment, because the throughput per user is improved, it is easy to cope with a large machine learning model. For example, because the SRAM has a limited storage capacity, a large number of processors need to be allocated to one machine learning model when the inference process of a large machine learning model is to be performed. In addition, when the throughput per user improves, latency or bandwidth requirements of an inter-chip network are reduced. As a result, a cost of the entire system can be reduced.

A part or all of the inference process performed by the computing device 100 described above may be implemented by hardware, or may be implemented by information processing by software (program) executed by a CPU, a graphics processing unit (GPU), or the like. In a case where the information processing is implemented by the information processing by software, the information processing by software may be executed by storing the software that implements at least a part of the functions of the information processing performed by the computing device 100 in a non-transitory storage medium (non-transitory computer-readable storage medium), such as a compact disc-read only memory (CD-ROM), a universal serial bus (USB) memory, or the like and causing a computer to read the software. The software may be downloaded via a communication network. Further, all of or a part of the software processing may be implemented by a circuit, such as an application specific integrated circuit (ASIC), an FPGA, or the like, and the information processing by software may be implemented by hardware.

The storage medium that stores the software may be a removable medium, such as an optical disk or the like, or a fixed storage medium, such as a hard disk, a memory, or the like. The storage medium may be provided inside the computer (a main storage device, an auxiliary storage device, or the like), or may be provided outside the computer.

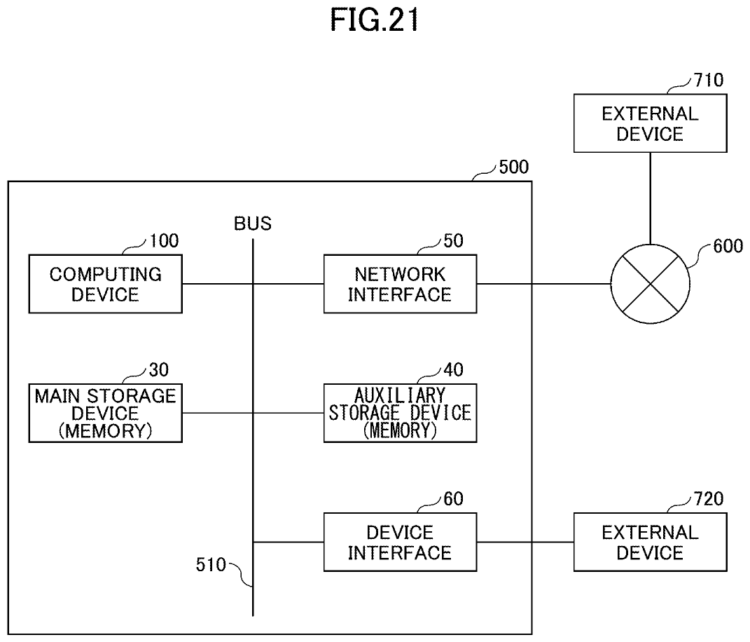

FIG. 21 is a block diagram illustrating an example of a hardware configuration of a computer equipped with the computing device 100 described above. In the following description, it is assumed that the computer is equipped with the computing device 100. In FIG. 21, the computer may be implemented as a computer 500 including the computing device 100, a main storage device 30 (memory), an auxiliary storage device 40 (memory), a network interface 50, and a device interface 60 that are connected to one another via a bus 510, for example.

The computer 500 illustrated in FIG. 21 includes one of each of the constituent elements, but may include a plurality of the same constituent elements. Further, although one computer 500 is illustrated in FIG. 21, the software may be installed in a plurality of computers, and the plurality of computers may perform the same or different partial processes of the software. In this case, the plurality of computers may communicate with one another via the network interface 50 or the like to perform the processing in a distributed computing mode. That is, a system may be configured in which functions are realized by one or more computers 500 executing instructions stored in one or more storage devices. Further, information transmitted from a terminal may be processed by one or more cloud-based computers 500, and the processing results may be transmitted to the terminal.

Various computations may be performed by parallel processing, using one or more computing devices 100 of the computer 500 or using a plurality of computers 500 via a network. In addition, the various computations may be distributed to the processing elements PE, which are an example of a plurality of computational cores provided in the computing device 100, and may be performed by parallel processing. Further, a part of or all of the processes, means, and the like of the present disclosure may be implemented by at least one of a cloud-based processor or a cloud-based storage device that can communicate with the computer 500 via a network. Accordingly, each device in the embodiment described above may be in the form of one or more computers performing parallel computing.

The computing device 100 may be an electronic circuit (a processing circuit, processing circuitry, a CPU, a GPU, an FPGA, an ASIC, or the like) that performs at least one of control or computation of the computer. The computing device 100 may be a dedicated processing circuit designed to perform a specific computation or a computer including both a general-purpose processor and a dedicated processing circuit. In addition, the computing device 100 may include an optical circuit or may include an arithmetic function based on quantum computing.

The computing device 100 may perform the computation process based on data or software input from a device or the like of the internal constituent elements or components of the computer 500, and may output computation results or control signals to the device or the like. The computing device 100 may control each constituent element or component constituting the computer 500 by executing an operating system (OS), an application, or the like of the computer 500.

The inference process of the machine learning model in the embodiment described above may be implemented by one or a plurality of computing devices 100. In this case, the computing device 100 may refer to one or more electronic circuits disposed on one chip, or may refer to one or more electronic circuits disposed on two or more chips or on two or more devices. In a case where the plurality of electronic circuits are used, the electronic circuits may communicate with one another by wired or wireless connection.

The main storage device 30 may store instructions to be executed by the computing device 100, various data, and the like, and information stored in the main storage device 30 may be read by the computing device 100. The auxiliary storage device 40 is a storage device other than the main storage device 30. These storage devices refer to arbitrary electronic components capable of storing electronic information, and may be semiconductor memories. The semiconductor memory may be either a volatile memory or a nonvolatile memory. A storage device for storing various data and the like in the computer 500 may be implemented by the main storage device 30 or the auxiliary storage device 40, or may be implemented by a built-in memory of the computing device 100.

In a case where the computer 500 is configured by at least one storage device (memory) and at least one computing device 100 connected (coupled) to the at least one storage device, the at least one computing device 100 may be connected to one storage device. In addition, at least one storage device may be connected to one computing device 100. Moreover, the configuration of the computer 500 may include at least one computing device 100 among a plurality of computing devices 100 is connected to at least one storage device among a plurality of storage devices. Further, this configuration may be implemented by the storage devices and the computing devices 100 included in a plurality of computers 500. The storage device may have a configuration (for example, a cache memory including a L1 cache and a L2 cache) integrated with the computing device 100.

The network interface 50 is an interface for connecting to a communication network 600 by wireless or wired connection. The network interface 50 may be an appropriate interface, such as an interface in conformance with an existing communication standard or the like. The network interface 50 may exchange information with an external device 710 that is connected to the computer 500 via a communication network 600. The communication network 600 may be any one of or a combination of a wide area network (WAN), a local area network (LAN), a personal area network (PAN), and the like. The communication network 600 may be any network that enables information to be exchanged between the computer 500 and the external device 710. Examples of the WAN include the Internet or the like, examples of the LAN include IEEE 802.11, the Ethernet (registered trademark), or the like, and examples of the PAN include the Bluetooth (registered trademark), near field communication (NFC), or the like.

The device interface 60 is an interface, such as a USB or the like, that directly connects to the external device 720.

The external device 710 is a device connected to the computer 500 via a network. The external device 720 is a device directly connected to the computer 500.

The external device 710 or the external device 720 may be an input device, for example. The input device is a device, such as a camera, a microphone, a motion capture, various sensors, a keyboard, a mouse, a touchscreen panel, or the like, for example, and provides acquired information to the computer 500. The external device 710 or the external device 720 may be a device including an input device, a memory, and a processor, such as a personal computer, a tablet terminal, a smartphone, or the like.

The external device 710 or the external device 720 may be an output device, for example. The output device may be a display device, such as a liquid crystal display (LCD), an organic electro luminescence (EL) panel, or the like, for example, and may be a speaker or the like that outputs audio and other sounds. In addition, the external device 710 or the external device 720 may be a device including an output device, a memory, and a processor, such as a personal computer, a tablet terminal, a smartphone, or the like.

Further, the external device 710 or the external device 720 may be a storage device (memory). For example, the external device 710 may be a network storage or the like, and the external device 720 may be a storage, such as a hard disk drive (HDD) or the like.

The external device 710 or the external device 720 may be a device having some of the functions of the constituent elements or components of the computer 500. That is, the computer 500 may transmit a part of or all of the processing results to the external device 710 or the external device 720, or may receive a part of or all of the processing results from the external device 710 or the external device 720.

According to the disclosed technique, it is possible to provide a computing device having a large storage capacity and a large bandwidth.

In the present specification (including the claims), if the expression “at least one of a, b, and c” or “at least one of a, b, or c” is used (including similar expressions), any one of a, b, c, a-b, a-c, b-c, or a-b-c is included. Multiple instances may also be included in any of the elements, such as a-a, a-b-b, and a-a-b-b-c-c. Further, the addition of another element other than the listed elements (a, b, and c), such as adding d as a-b-c-d, is included.

In the present specification (including the claims), if the expression such as “in response to data being input”, “using data”, “based on data”, “according to data”, or “in accordance with data” (including similar expressions) is used, unless otherwise indicated, a case in which the data itself is used as an input and a case in which data obtained by performing some kind of processing on the data (for example, data added with noise, normalized data, features extracted from data, intermediate representation of data, and the like) is used as the input are included. If it is described that any result can be obtained “in response to data being input”, “using data”, “based on data”, “according to data”, or “in accordance with data” (including similar expressions) is used, unless otherwise indicated, a case in which the result is obtained based solely on the data is included, and a case in which the result is obtained by receiving the effects of data other than the data, factors, conditions, and/or states may be included. If it is described that “data is output” (including similar expressions), unless otherwise indicated, a case in which the data itself is used as an output is included, and a case in which data obtained by performing some kind of processing on the data (for example, data added with noise, normalized data, features extracted from data, intermediate representation of data, and the like) is used as the output is included.

In the present specification (including the claims), if the terms “connected” and “coupled” are used, the terms are intended as non-limiting terms that include any of directly connected/coupled, indirectly connected/coupled, electrically connected/coupled, communicatively connected/coupled, operatively connected/coupled, physically connected/coupled, and the like. Such terms should be interpreted according to a context in which the terms are used, but a connected/coupled form that is not intentionally or naturally excluded should be interpreted as being included in the terms without being limited.

In the present specification (including the claims), if the expression “A configured to B” is used, a case in which a physical structure of the element A has a configuration that can perform the operation B, and a permanent or temporary setting/configuration of the element A is configured/set to actually perform the operation B may be included. For example, if the element A is a general-purpose processor, the processor may have a hardware configuration that can perform the operation B and be configured to actually perform the operation B by setting a permanent or temporary program (that is, an instruction). If the element A is a dedicated processor, a dedicated arithmetic circuit, or the like, a circuit structure or the like of the processor may be implemented so as to actually perform the operation B irrespective of whether the control instruction and the data are actually attached.

In the present specification (including the claims), if a term indicating inclusion or possession (for example, “comprising”, “including”, “having”, and the like) is used, the term is intended as an open-ended term, including inclusion or possession of an object other than a target object indicated by the object of the term. If the object of the term indicating inclusion or possession is an expression that does not specify a quantity or that suggests a singular number (that is, an expression using “a” or “an” as an article), the expression should be interpreted as being not limited to a specified number.

In the present specification (including the claims), even if an expression such as “one or more” or “at least one” is used in a certain description, and an expression that does not specify a quantity or that suggests a singular number (that is, an expression using “a” or “an” as an article) is used in another description, it is not intended that the latter expression indicates “one”. Generally, an expression that does not specify a quantity or that suggests a singular number (that is, an expression using “a” or “an” as an article) should be interpreted as being not necessarily limited to a particular number.

In the present specification, if it is described that a particular advantage/result is obtained in a particular configuration included in an embodiment, unless there is a particular reason, it should be understood that the advantage/result may be obtained in another embodiment or other embodiments including the configuration. It should be understood, however, that the presence or absence of the advantage/result generally depends on various factors, conditions, states, and/or the like, and that the advantage/result is not necessarily obtained by the configuration. The advantage/result is merely an advantage/result that is obtained by the configuration described in the embodiment when various factors, conditions, and/or states are satisfied, and is not necessarily obtained in the invention according to the claim that defines the configuration or a similar configuration.

In the present specification (including the claims), if a term such as “maximize/maximization” is used, the term includes obtaining a global maximum value, obtaining an approximate value of the global maximum value, obtaining a local maximum value, and obtaining an approximate value of the local maximum value, and should be interpreted as appropriate depending on the context in which the term is used. These terms also include finding approximate values of the maximum values stochastically or heuristically. Similarly, the use of a term such as “minimize/minimization” includes obtaining a global minimum, obtaining an approximate value of the global minimum, obtaining a local minimum, and obtaining an approximate value of the local minimum, and should be interpreted as appropriate depending on the context in which the term is used. These terms also include finding approximate values of the minimum values stochastically or heuristically. Similarly, terms such as “optimize/optimization” and the like include obtaining a global optimum, obtaining an approximate value of the global optimum, obtaining a local optimum, and obtaining an approximate value of the local optimum, and should be interpreted as appropriate depending on the context in which the term is used. These terms also include finding approximate values of the optimal values stochastically or heuristically.

In the present specification (including the claims), if multiple hardware performs predetermined processes, each of the hardware may cooperate to perform the predetermined processes, or some of the hardware may perform all of the predetermined processes. Additionally, some of the hardware may perform some of the predetermined processes while other hardware may perform the remainder of the predetermined processes. In the present specification (including the claims), if an expression such as “one or more hardware perform a process A and the one or more hardware perform a process B” is used, the hardware that performs the process A may be the same as or different from the hardware that performs the process B. That is, the hardware that performs the process A and the hardware that performs the process B may be included in the one or more hardware. The hardware may include an electronic circuit, a device including the electronic circuit, or the like.

In the present specification (including the claims), if multiple storage devices (memories) store data, each of the multiple storage devices (memories) may store only a portion of the data or may store an entirety of the data. In addition, some storage devices among the multiple storage devices may be configured to store the data.

Although the embodiments of the present disclosure have been described in detail above, the present disclosure is not limited to the individual embodiments described above. Various additions, modifications, substitutions, partial deletions, and the like can be made without departing from the conceptual idea and spirit of the invention derived from the contents defined in the claims and the equivalents thereof. For example, in all the embodiments described above, the numerical values used in the description are described as examples and the embodiments are not limited thereto. Additionally, the order of the operations in the embodiments is described as an example and the embodiments are not limited thereto.

Various aspects of the subject-matter described herein may be set out non-exhaustively in the following numbered clauses:

(Clause 1) A computing device comprising:
a plurality of arithmetic units;
one or more first memories coupled to the plurality of arithmetic units; and
one or more second memories coupled to the plurality of arithmetic units, wherein:
the one or more second memories and the plurality of arithmetic units are stacked relative to one another, and
at least a part of data stored in the one or more second memories is used by one or more of the plurality of arithmetic units without passing through the one or more first memories.

(Clause 2) The computing device according to clause 1, further comprising:
a first die including the plurality of arithmetic units and the one or more first memories; and
a second die including the one or more second memories.

(Clause 3) The computing device according to clause 2, wherein:
the first die and the second die are stacked relative to each other and disposed on a substrate, and
the first die and the second die are connected to each other by face-to-face bonding.

(Clause 4) The computing device according to clause 3, wherein the first die and the second die are connected to each other by hybrid bonding.

(Clause 5) The computing device according to clause 2, wherein:
the first die and the second die are stacked relative to each other and disposed on a substrate, and
the first die and the second die are connected to each other by back-to-face bonding.

(Clause 6) The computing device according to clause 5, wherein one die of the first die and the second die, farther away from the substrate than the other die of the first die and the second die, is coupled to the other die closer to the substrate than the one die through a through-via provided in the one die.

(Clause 7) The computing device according to clause 2, wherein the first die and a plurality of second dies are stacked relative to one another and disposed on a substrate.

(Clause 8) The computing device according to any one of clauses 2 to 7, wherein the second die includes:
one or more redundant memories; and
a switching circuit configured to disconnect a faulty memory among the one or more second memories from the first die, and to electrically connect the one or more redundant memories to the first die.

(Clause 9) The computing device according to any one of clauses 1 to 8, wherein the plurality of arithmetic units includes one or more first arithmetic units and one or more second arithmetic units, the computing device further comprising:
a first memory interface configured to couple at least one first arithmetic unit of the one or more first arithmetic units to the one or more second memories; and
a second memory interface configured to couple at least one second arithmetic unit of the one or more second arithmetic units to the one or more second memories.

(Clause 10) The computing device according to clause 9, wherein:
the first memory interface couples the at least one first arithmetic unit of the one or more first arithmetic units to a first predetermined second memory of the one or more second memories, and
the second memory interface couples the at least one second arithmetic unit of the one or more second arithmetic units to another predetermined second memory of the one or more second memories.

(Clause 11) The computing device according to any one of clauses 1 to 10, wherein the one or more second memories include one or more DRAMs.

(Clause 12) The computing device according to clause 11, wherein the one or more DRAMs are scratchpad memories of the plurality of arithmetic units.

(Clause 13) The computing device according to any one of clauses 1 to 12, further comprising:
a plurality of second hierarchical blocks each including the plurality of arithmetic units and the one or more first memories; and
one or more third memories coupled to the plurality of second hierarchical blocks,
wherein the plurality of arithmetic units included in each of the plurality of second hierarchical blocks and the one or more second memories are stacked relative to one another.

(Clause 14) The computing device according to clause 13, further comprising:
a plurality of first hierarchical blocks each including two or more arithmetic units included in the plurality of arithmetic units,
wherein each of the plurality of second hierarchical blocks includes the plurality of first hierarchical blocks.

(Clause 15) The computing device according to clause 14, wherein each of the plurality of first hierarchical blocks includes one or more third arithmetic units provided in common to the two or more arithmetic units.

(Clause 16) The computing device according to any one of clauses 13 to 15, further comprising:
a plurality of third hierarchical blocks each including the plurality of second hierarchical blocks and the one or more third memories; and
one or more fourth memories.

(Clause 17) The computing device according to any one of clauses 1 to 16, wherein each arithmetic unit of the plurality of arithmetic units includes one or more fifth memories having a capacity smaller than a capacity of the one or more first memories.

(Clause 18) The computing device according to any one of clauses 2 to 8, further comprising:
a third die including one or more third memories,
wherein the third die and the second die are stacked relative to each other.

(Clause 19) The computing device according to any one of clauses 1 to 18, wherein the computing device has a SIMD architecture.

(Clause 20) The computing device according to any one of clauses 1 to 19, wherein:
the one or more second memories store parameters of a machine learning model and intermediate data computed using the machine learning model, and
the plurality of arithmetic units acquire the parameters and the intermediate data from the one or more second memories and perform a first process using the acquired parameters and the acquired intermediate data.

(Clause 21) The computing device according to clause 20, wherein:
the one or more second memories store intermediate data newly generated by performing the first process, and
the plurality of arithmetic units acquire the parameters, the intermediate data, and the newly generated intermediate data from the one or more second memories, and perform a second process using the acquired parameters, the acquired intermediate data, and the acquired newly generated intermediate data.

(Clause 22) The computing device according to clause 21, wherein each process of the first process and the second process includes a process of generating one or more pieces of output information using the machine learning model.

(Clause 23) The computing device according to any one of clauses 20 to 22, wherein the following process is repeated until a predetermined condition is satisfied:
the plurality of arithmetic units acquire the parameters and the intermediate data from the one or more second memories,
the plurality of arithmetic units perform a process using the acquired parameters and the acquired intermediate data, and
the one or more second memories store intermediate data newly generated by performing the process as a part of the intermediate data.

(Clause 24) The computing device according to any one of clauses 20 to 23, wherein the machine learning model includes at least one of a transformer or a state space model.

(Clause 25) The computing device according to clause 24, wherein:
the machine learning model includes the transformer, and
the intermediate data includes at least a part of key vectors and value vectors used in an attention mechanism of the transformer.

(Clause 26) The computing device according to clause 24, wherein:
the machine learning model includes the state space model, and
the intermediate data includes at least a part of states in the state space model.

(Clause 27) A computing method implemented in a computing device that includes a plurality of arithmetic units, one or more first memories coupled to the plurality of arithmetic units, and one or more second memories coupled to the plurality of arithmetic units, wherein the one or more second memories and the plurality of arithmetic units are stacked relative to one another, and at least a part of data stored in the one or more second memories is used by one or more of the plurality of arithmetic units without passing through the one or more first memories, the computing method comprising:
storing, in the one or more second memories, parameters of a machine learning model and intermediate data computed using the machine learning model;
acquiring, by the plurality of arithmetic units, the parameters and the intermediate data from the one or more second memories; and
performing, by the plurality of arithmetic units, a first process using the acquired parameters and the acquired intermediate data.

The process performed by the computing device according to any one of clauses 20 to 26 may be achieved by the computing device according to any one of clauses 1 to 19 by executing an instruction generated by a compiler device.

What is claimed is:

1. A computing device comprising:
a plurality of arithmetic units;
one or more first memories coupled to the plurality of arithmetic units;
one or more second memories coupled to the plurality of arithmetic units;
a plurality of second hierarchical blocks each including the plurality of arithmetic units and the one or more first memories; and
one or more third memories coupled to the plurality of second hierarchical blocks, wherein:
the plurality of arithmetic units included in each of the plurality of second hierarchical blocks and the one or more second memories are stacked relative to one another, and
at least a part of data stored in the one or more second memories is used by one or more of the plurality of arithmetic units without passing through the one or more first memories.

2. The computing device as claimed in claim 1, further comprising:
a first die including the plurality of arithmetic units and the one or more first memories; and
a second die including the one or more second memories, wherein:
the first die and the second die are stacked relative to each other and disposed on a substrate, and
the first die and the second die are connected to each other by face-to-face bonding.

3. The computing device as claimed in claim 2, wherein the first die and the second die are connected to each other by hybrid bonding.

4. The computing device as claimed in claim 1, further comprising:
a first die including the plurality of arithmetic units and the one or more first memories; and
a second die including the one or more second memories,
wherein the second die includes:
one or more redundant memories; and
a switching circuit configured to disconnect a faulty memory among the one or more second memories from the first die, and to electrically connect the one or more redundant memories to the first die.

5. The computing device as claimed in claim 1, wherein the plurality of arithmetic units include one or more first arithmetic units and one or more second arithmetic units, the computing device further comprising:
a first memory interface configured to couple at least one first arithmetic unit of the one or more first arithmetic units to the one or more second memories; and
a second memory interface configured to couple at least one second arithmetic unit of the one or more second arithmetic units to the one or more second memories.

6. The computing device as claimed in claim 5, wherein:
the first memory interface couples the at least one first arithmetic unit of the one or more first arithmetic units to a predetermined second memory of the one or more second memories, and
the second memory interface couples the at least one second arithmetic unit of the one or more second arithmetic units to another predetermined second memory of the one or more second memories.

7. The computing device as claimed in claim 1, wherein:
the one or more second memories include one or more DRAMs, and
the one or more DRAMs are scratchpad memories of the plurality of arithmetic units.

8. The computing device as claimed in claim 1, further comprising:
a plurality of first hierarchical blocks each including two or more arithmetic units included in the plurality of arithmetic units,
wherein each of the plurality of second hierarchical blocks includes the plurality of first hierarchical blocks.

9. The computing device as claimed in claim 8, wherein each of the plurality of first hierarchical blocks includes one or more third arithmetic units provided in common to the two or more arithmetic units.

10. The computing device as claimed in claim 1, further comprising:
a plurality of third hierarchical blocks each including the plurality of second hierarchical blocks and the one or more third memories; and
one or more fourth memories.

11. The computing device as claimed in claim 1, wherein the computing device has a SIMD architecture.

12. The computing device as claimed in claim 1, wherein:
the one or more second memories store parameters of a machine learning model and intermediate data computed using the machine learning model,
the plurality of arithmetic units acquire the parameters and the intermediate data from the one or more second memories and perform a first process using the acquired parameters and the acquired intermediate data, and
the machine learning model includes at least one of a transformer or a state space model.

13. The computing device as claimed in claim 12, wherein:
the machine learning model includes the transformer, and
the intermediate data includes at least a part of key vectors and value vectors used in an attention mechanism of the transformer.

14. The computing device as claimed in claim 12, wherein:
the machine learning model includes the state space model, and
the intermediate data includes at least a part of states in the state space model.

15. The computing device as claimed in claim 12, wherein the computing device has a SIMD architecture.

16. A computing device comprising:
a plurality of arithmetic units;
one or more first memories coupled to the plurality of arithmetic units; and
one or more second memories coupled to the plurality of arithmetic units, wherein:
the one or more second memories and the plurality of arithmetic units are stacked relative to one another,
at least a part of data stored in the one or more second memories is used by one or more of the plurality of arithmetic units without passing through the one or more first memories, and
the computing device has a SIMD architecture.

17. The computing device as claimed in claim 16, further comprising:
a first die including the plurality of arithmetic units and the one or more first memories; and
a second die including the one or more second memories, wherein:
the first die and the second die are stacked relative to each other and disposed on a substrate, and
the first die and the second die are connected to each other by face-to-face bonding.

18. The computing device as claimed in claim 17, wherein the first die and the second die are connected to each other by hybrid bonding.

19. The computing device as claimed in claim 16, further comprising:
a first die including the plurality of arithmetic units and the one or more first memories; and
a second die including the one or more second memories,
wherein the second die includes:
one or more redundant memories; and
a switching circuit configured to disconnect a faulty memory among the one or more second memories from the first die, and to electrically connect the one or more redundant memories to the first die.

20. The computing device as claimed in claim 16, wherein the plurality of arithmetic units include one or more first arithmetic units and one or more second arithmetic units, the computing device further comprising:
a first memory interface configured to couple at least one first arithmetic unit of the one or more first arithmetic units to the one or more second memories; and
a second memory interface configured to couple at least one second arithmetic unit of the one or more second arithmetic units to the one or more second memories.

21. The computing device as claimed in claim 20, wherein:
the first memory interface couples the at least one first arithmetic unit of the one or more first arithmetic units to a predetermined second memory of the one or more second memories, and
the second memory interface couples the at least one second arithmetic unit of the one or more second arithmetic units to another predetermined second memory of the one or more second memories.

22. The computing device as claimed in claim 16, wherein:
the one or more second memories include one or more DRAMs, and
the one or more DRAMs are scratchpad memories of the plurality of arithmetic units.

23. The computing device as claimed in claim 16, wherein:
the one or more second memories store parameters of a machine learning model and intermediate data computed using the machine learning model,
the plurality of arithmetic units acquire the parameters and the intermediate data from the one or more second memories and perform a first process using the acquired parameters and the acquired intermediate data, and
the machine learning model includes at least one of a transformer or a state space model.

24. The computing device as claimed in claim 23, wherein:
the machine learning model includes the transformer, and
the intermediate data includes at least a part of key vectors and value vectors used in an attention mechanism of the transformer.

25. The computing device as claimed in claim 23, wherein:
the machine learning model includes the state space model, and
the intermediate data includes at least a part of states in the state space model.

26. A computing device comprising:
a plurality of arithmetic units;
one or more first memories coupled to the plurality of arithmetic units; and
one or more second memories coupled to the plurality of arithmetic units, wherein:
the one or more second memories and the plurality of arithmetic units are stacked relative to one another,
at least a part of data stored in the one or more second memories is used by one or more of the plurality of arithmetic units without passing through the one or more first memories,
the one or more second memories store parameters of a machine learning model and intermediate data computed using the machine learning model,
the plurality of arithmetic units acquire the parameters and the intermediate data from the one or more second memories and perform a first process using the acquired parameters and the acquired intermediate data, and
the machine learning model includes at least one of a transformer or a state space model.

27. The computing device as claimed in claim 26, further comprising:
a first die including the plurality of arithmetic units and the one or more first memories; and
a second die including the one or more second memories, wherein:
the first die and the second die are stacked relative to each other and disposed on a substrate, and
the first die and the second die are connected to each other by face-to-face bonding.

28. The computing device as claimed in claim 27, wherein the first die and the second die are connected to each other by hybrid bonding.

29. The computing device as claimed in claim 26, further comprising:
a first die including the plurality of arithmetic units and the one or more first memories; and
a second die including the one or more second memories,
wherein the second die includes:
one or more redundant memories; and
a switching circuit configured to disconnect a faulty memory among the one or more second memories from the first die, and to electrically connect the one or more redundant memories to the first die.

30. The computing device as claimed in claim 26, wherein the plurality of arithmetic units include one or more first arithmetic units and one or more second arithmetic units, the computing device further comprising:
a first memory interface configured to couple at least one first arithmetic unit of the one or more first arithmetic units to the one or more second memories; and
a second memory interface configured to couple at least one second arithmetic unit of the one or more second arithmetic units to the one or more second memories.

31. The computing device as claimed in claim 30, wherein:
the first memory interface couples the at least one first arithmetic unit of the one or more first arithmetic units to a predetermined second memory of the one or more second memories, and
the second memory interface couples the at least one second arithmetic unit of the one or more second arithmetic units to another predetermined second memory of the one or more second memories.

32. The computing device as claimed in claim 26, wherein:
the one or more second memories include one or more DRAMs, and
the one or more DRAMs are scratchpad memories of the plurality of arithmetic units.

33. The computing device as claimed in claim 26, wherein:
the machine learning model includes the transformer, and
the intermediate data includes at least a part of key vectors and value vectors used in an attention mechanism of the transformer.

34. The computing device as claimed in claim 26, wherein:
the machine learning model includes the state space model, and
the intermediate data includes at least a part of states in the state space model.

35. A computing method implemented in a computing device that includes a plurality of arithmetic units, one or more first memories coupled to the plurality of arithmetic units, and one or more second memories coupled to the plurality of arithmetic units, wherein the one or more second memories and the plurality of arithmetic units are stacked relative to one another, and at least a part of data stored in the one or more second memories is used by one or more of the plurality of arithmetic units without passing through the one or more first memories, the computing method comprising:
storing, in the one or more second memories, parameters of a machine learning model and intermediate data computed using the machine learning model;
acquiring, by the plurality of arithmetic units, the parameters and the intermediate data from the one or more second memories; and
performing, by the plurality of arithmetic units, a first process using the acquired parameters and the acquired intermediate data,
wherein the machine learning model includes at least one of a transformer or a state space model.

36. The computing method as claimed in claim 35, wherein:
the one or more second memories store intermediate data newly generated by performing the first process, and
the plurality of arithmetic units acquire the parameters, the intermediate data, and the newly generated intermediate data from the one or more second memories, and perform a second process using the acquired parameters, the acquired intermediate data, and the acquired newly generated intermediate data.

37. The computing method as claimed in claim 36, wherein each process of the first process and the second process includes a process of generating one or more pieces of output information using the machine learning model.

38. The computing method as claimed in claim 35, wherein the following process is repeated until a predetermined condition is satisfied:
the plurality of arithmetic units acquire the parameters and the intermediate data from the one or more second memories,
the plurality of arithmetic units perform a process using the acquired parameters and the acquired intermediate data, and
the one or more second memories store intermediate data newly generated by performing the process as a part of the intermediate data.

39. The computing method as claimed in claim 38, wherein:
the machine learning model includes the transformer, and
the intermediate data includes at least a part of key vectors and value vectors used in an attention mechanism of the transformer.

40. The computing method as claimed in claim 38, wherein:
the machine learning model includes the state space model, and
the intermediate data includes at least a part of states in the state space model.
